(19) United States
(12) Patent Application Publication
(10) Pub. No.: US 2026/0190926 A1
(43) Pub. Date: Jul. 2, 2026

(54) METHOD OF FORMING AN ELECTROMAGNETIC INTERFERENCE (EMI) SHIELDING FILM AND APPARATUS FOR EFFECTING THE SAME

(71) Applicant: Taiwan Semiconductor Manufacturing Company Limited, Hsinchu (TW)

(72) Inventors: Chih-Chien Pan, Taipei City (TW); Li-Hui Cheng, New Taipei City (TW); Pu Wang, Hsinchu City (TW)

(21) Appl. No.: 19/004,367

(22) Filed: Dec. 29, 2024

(51) Int. Cl. H01L 21/673; C23C 16/455; H01L 23/552

(52) U.S. Cl. CPC H10P 72/16; C23C 16/45561; H10W 42/20

(57) ABSTRACT

A device structure may be manufactured by: disposing a semiconductor package on a package tray, wherein the package tray includes a tray base portion which laterally extends underneath the semiconductor package, a tray mesa portion which protrudes upward from the tray base portion and including a contiguous set of mesa-portion sidewalls, and a frame-shaped support portion including a continuous set of support-portion outer sidewalls that is laterally offset inward from a package area that is defined by a set of all sidewalls of the semiconductor package in a plan view; and anisotropically depositing an electromagnetic interference (EMI) shielding film on the set of all sidewalls of the semiconductor package and on a top surface of the semiconductor package.

### BACKGROUND

An electromagnetic interference (EMI) shielding film on a semiconductor package blocks external electromagnetic waves from interfering with semiconductor devices within the semiconductor package. An EMI shielding film may be used to prevent signal degradation, and to ensure normal operation of semiconductor devices within a semiconductor package in the presence of strong external electromagnetic signals.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a structure that includes a first carrier substrate and redistribution structures according to an embodiment of the present disclosure.

FIG. 1B is a top-down view of the region of the structure of FIG. 1A.

FIG. 2A is vertical cross-sectional view of a region of the structure after formation of on-interposer bump structures according to an embodiment of the present disclosure.

FIG. 2B is a top-down view of the region of the structure of FIG. 2A.

FIG. 3A is a vertical cross-sectional view of a region the structure after attaching semiconductor dies according to an embodiment of the present disclosure.

FIG. 3B is a top-down view of the region of the structure of FIG. 3A.

FIG. 3C is a top-down view of a region of an alternative configuration of the structure of FIG. 3A.

FIG. 3D is a top-down view of a region of another alternative configuration of the structure of FIG. 3A.

FIG. 3E is a magnified vertical cross-sectional view of a high bandwidth memory die.

FIG. 4 is a vertical cross-sectional view of the structure after formation of first underfill material portions.

FIG. 5A is a vertical cross-sectional view of the structure after formation of an epoxy molding compound (EMC) matrix according to an embodiment of the present disclosure.

FIG. 5B is a horizontal cross-sectional view of the structure along the horizontal plane B-B′ of FIG. 5A.

FIG. 6 is a vertical cross-sectional view of a region of the structure after attaching a second carrier substrate and detaching the first carrier substrate according to an embodiment of the present disclosure.

FIG. 7 is a vertical cross-sectional view of a region of the structure after formation of bump structures and second solder material portions according to an embodiment of the present disclosure.

FIG. 8 is a vertical cross-sectional view of a region of the structure after detaching the second carrier substrate according to an embodiment of the present disclosure.

FIG. 9 is a vertical cross-sectional view of a region of the structure during dicing of a redistribution substrate and the EMC matrix according to an embodiment of the present disclosure.

FIG. 10A is a vertical cross-sectional view of a semiconductor package according to an embodiment of the present disclosure.

FIG. 10B is a horizontal cross-sectional view of the semiconductor package along the horizontal plane B-B′ of FIG. 10A.

FIG. 11A is a vertical cross-sectional view of an exemplary deposition apparatus in a first configuration according to an embodiment of the present disclosure.

FIG. 11B is a vertical cross-sectional view of an exemplary deposition apparatus in a second configuration according to an embodiment of the present disclosure.

FIG. 11C is a vertical cross-sectional view of a region around a semiconductor package and a region of a package tray after disposing the semiconductor package on the package tray in the first exemplary deposition apparatus or in the second exemplary deposition apparatus according to an embodiment of the present disclosure.

FIG. 11D is a horizontal cross-sectional view of the portion of the package tray along the horizontal plane D-D′ in FIG. 11C.

FIG. 11E is a plan view of a larger portion of the package tray in FIGS. 11C and 11D.

FIG. 12A is a vertical cross-sectional view of the exemplary deposition apparatus in the first configuration at an end of an electromagnetic interference (EMI) shielding film deposition process according to an embodiment of the present disclosure.

FIG. 12B is a vertical cross-sectional view of the exemplary deposition apparatus in the second configuration at the end of the EMI shielding film deposition process according to an embodiment of the present disclosure.

FIG. 12C is a vertical cross-sectional view of a region around a semiconductor package and a region of a package tray in a first configuration at the end of an EMI shielding film deposition process according to an embodiment of the present disclosure.

FIG. 12D is a horizontal cross-sectional view of the portion of the package tray along the horizontal plane D-D′ in FIG. 12C.

FIG. 12E is a vertical cross-sectional view of a region around a semiconductor package and a region of a package tray in a second configuration at the end of an EMI shielding film deposition process according to an embodiment of the present disclosure.

FIG. 12F is a vertical cross-sectional view of a region around a semiconductor package and a region of a package tray in a third configuration at the end of an EMI shielding film deposition process according to an embodiment of the present disclosure.

FIG. 13 is a vertical cross-sectional view of a structure after attaching the semiconductor package to the packaging substrate and after forming a second underfill material portion according to an embodiment of the present disclosure.

FIG. 14 is a vertical cross-sectional view of a structure after attaching a lid structure to the packaging substrate and to the semiconductor package according to an embodiment of the present disclosure.

FIG. 15 is a vertical cross-sectional view of the structure after the packaging substrate is attached to a printed circuit board (PCB) according to an embodiment of the present disclosure.

FIG. 16 is a first flowchart illustrating steps for forming an electromagnetic shielding film on a semiconductor package according to an embodiment of the present disclosure.

FIG. 17 is a second flowchart illustrating steps for forming an electromagnetic shielding film on a semiconductor package according to an embodiment of the present disclosure.

### DETAILED DESCRIPTION

The following disclosure provides many different embodiments, or examples, for implementing various features of the provided subject matter. Specific examples of components and arrangements are described below to simplify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features selected from elements as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

An electromagnetic interference (EMI) shielding film is a layer applied to semiconductor packages to block or reduce the effects of external electromagnetic radiation on internal electronic components. The EMI shielding film serves to prevent signal degradation, interference, and malfunction in the semiconductor devices caused by exposure to electromagnetic fields. In the semiconductor industry, EMI shielding films have been widely used to ensure the reliable operation of sensitive electronic devices by minimizing the impact of electromagnetic interference. An EMI shielding film may be deposited on semiconductor packages to provide a protective conductive barrier layer that effectively blocks external electromagnetic radiation.

In instances in which EMI shielding films are deposited on semiconductor packages positioned on a tray, issues such as backside contamination of bump structures, insufficient sidewall coating, and continuous EMI film formation between the package and the tray may arise. Backside contamination may lead to electrical short paths and device failure due to EMI film deposition on the bump structures. Inadequate sidewall coating results in poor EMI shielding performance. In addition, the formation of a continuous EMI film between the semiconductor package and the tray may create burrs during the pick-and-place process. Both conditions may complicate subsequent handling and assembly.

According to an aspect of the present disclosure, a package tray may be provided. The package tray may include a tray base portion, a tray mesa portion with a contiguous set of mesa-portion sidewalls, and a frame-shaped support portion. A semiconductor package may be disposed on the packaging tray such that the semiconductor package is supported only by the frame-shaped support portion. The frame-shaped support portion may be laterally offset inward from the package area defined by the set of all sidewalls of the semiconductor package. This geometrical feature ensures that the array of solder material portions (e.g., bump structures) at the bottom of the semiconductor package does not come into direct contact with the package tray, preventing contamination during deposition of an EMI shielding film. The frame-shaped support portion contacts the semiconductor package at a frame-shaped bottom surface segment, avoiding the formation of a continuous film between the package and the tray, thus preventing burr formation. The anisotropic deposition of the EMI shielding film ensures full coverage of the sidewalls and top surface of the semiconductor package, may enhance the EMI shielding performance. Thus, embodiments of the present disclosure may be advantageously utilized to mitigate against backside contamination of solder material portions, to achieve full sidewall coverage of the EMI shielding film, and mitigate against burr formation. The various aspects of the present disclosure are now described in detail with reference to accompanying drawings.

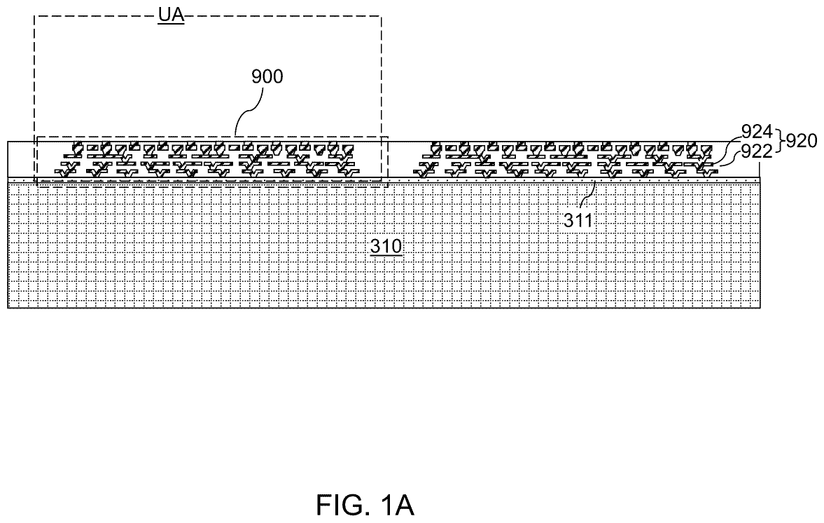

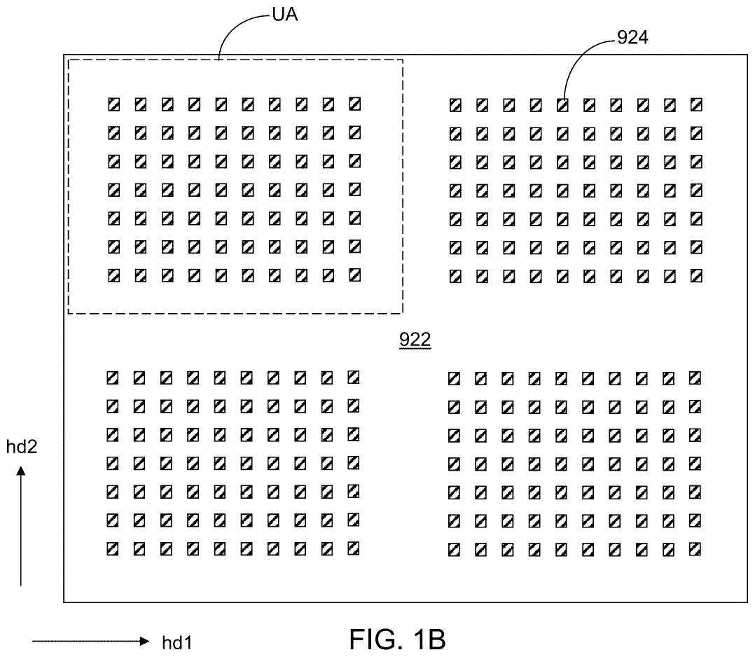

Referring to FIGS. 1A and 1B, an intermediate structure according to an embodiment of the present disclosure may include a first carrier substrate 310 and interposers 900 formed on a front side surface of the first carrier substrate 310. The first carrier substrate 310 may include an optically transparent substrate such as a glass substrate or a sapphire substrate. The diameter of the first carrier substrate 310 may be in a range from 150 mm to 290 mm, although lesser and greater diameters may be used. In addition, the thickness of the first carrier substrate 310 may be in a range from 500 microns to 2,000 microns, although lesser and greater thicknesses may also be used. Alternatively, the first carrier substrate 310 may be provided in a rectangular panel format. The dimensions of the first carrier in such alternative embodiments may be substantially the same.

A first adhesive layer 311 may be applied to the front-side surface of the first carrier substrate 310. In one embodiment, the first adhesive layer 311 may be a light-to-heat conversion (LTHC) layer. The LTHC layer may be a solvent-based coating applied using a spin coating method. The LTHC layer may convert ultraviolet light to heat, which may cause the material of the LTHC layer to lose adhesion. Alternatively, the first adhesive layer 311 may include a thermally decomposing adhesive material. For example, the first adhesive layer 311 may include an acrylic pressure-sensitive adhesive that decomposes at an elevated temperature. The debonding temperature of the thermally decomposing adhesive material may be in a range from 150 degrees to 200 degrees Celsius.

Interposers 900 may be formed over the first adhesive layer 311. Specifically, an interposer 900 may be formed within each unit area UA, which is the area of a repetition unit that may be repeated in a two-dimensional array over the first carrier substrate 310. Each interposer 900 includes a respective portion of a redistribution structure 920, which is a combination of redistribution dielectric layers 922 and redistribution wiring interconnects 924. The redistribution dielectric layers 922 are dielectric materials embedding the redistribution wiring interconnects 924. The redistribution dielectric layers 922 may be referred to as first dielectric layers or second dielectric layers in the claims of the instant application. The redistribution dielectric layers 922 include a respective dielectric polymer material such as polyimide (PI), benzocyclobutene (BCB), or polybenzobisoxazole (PBO). Other suitable materials may be within the contemplated scope of disclosure. Each redistribution dielectric layer 922 may be formed by spin coating and drying of the respective dielectric polymer material. The thickness of each redistribution dielectric layer 922 may be in a range from 2 microns to 40 microns, such as from 4 microns to 20 microns. Each redistribution dielectric layer 922 may be patterned, for example, by applying and patterning a respective photoresist layer thereabove, and by transferring the pattern in the photoresist layer into the redistribution dielectric layer 922 using an etch process such as an anisotropic etch process. The photoresist layer may be subsequently removed, for example, by ashing.

The redistribution wiring interconnects 924 are metallic connection structures, i.e., metallic structures that provide electrical connection. The redistribution wiring interconnects 924 may be referred to as first metallic connection structures or second metallic connection structures in the claims of the instant application. Each of the redistribution wiring interconnects 924 may be formed by depositing a metallic seed layer by sputtering, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm. The metallic fill material for the redistribution wiring interconnects 924 may include copper, nickel, or copper and nickel. Other suitable metallic fill materials are within the contemplated scope of disclosure. The thickness of the metallic fill material that is deposited for each redistribution wiring interconnect 924 may be in a range from 2 microns to 40 microns, such as from 4 microns to 10 microns, although lesser or greater thicknesses may also be used. The total number of levels of wiring in each interposer 900 (i.e., the levels of the redistribution wiring interconnects 924) may be in a range from 1 to 10. A periodic two-dimensional array (such as a rectangular array) of interposers 900 may be formed over the first carrier substrate 310. Each interposer 900 may be formed within a unit area UA. The layer including all interposers 900 is herein referred to as an interposer layer. The interposer layer includes a two-dimensional array of interposers 900. In one embodiment, the two-dimensional array of interposers 900 may be a rectangular periodic two-dimensional array of interposers 900 having a first periodicity along a first horizontal direction hd1 and having a second periodicity along a second horizontal direction hd2 that is perpendicular to the first horizontal direction hd1.

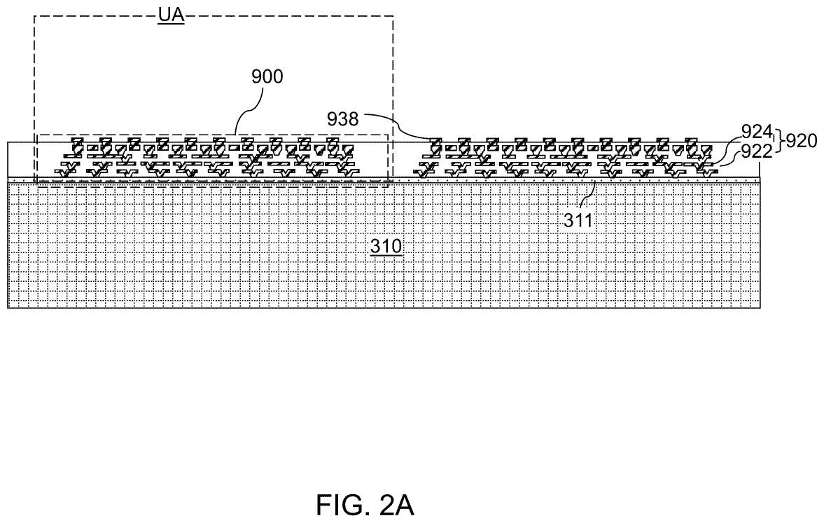

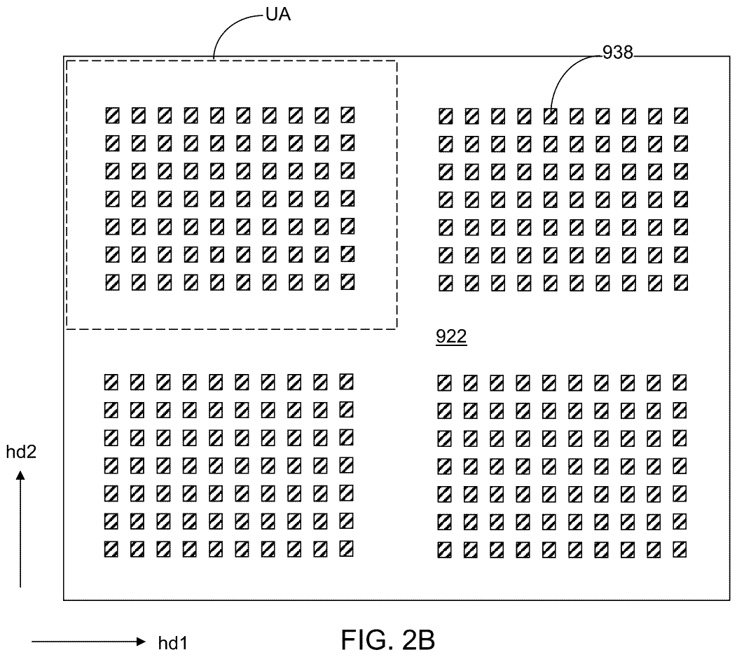

Referring to FIGS. 2A and 2B, at least one array of on-interposer bump structures 938 may be formed on the front surface of each interposer 900, i.e., with a portion of the redistribution structure 920 located within a respective unit area UA. A single array of on-interposer bump structures 938, or a plurality of arrays of on-interposer bump structures 938, may be formed on each interposer 900. In one embodiment, each array of on-interposer bump structures 938 may be formed as a respective periodic array such as a rectangular array.

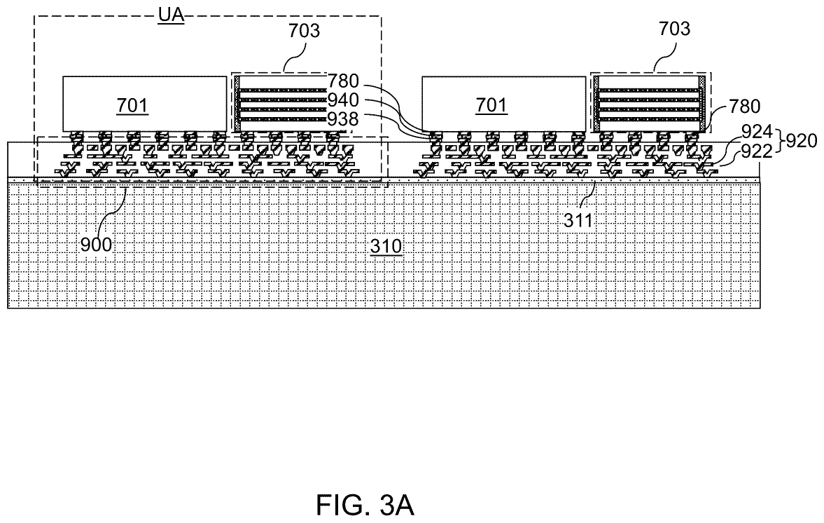

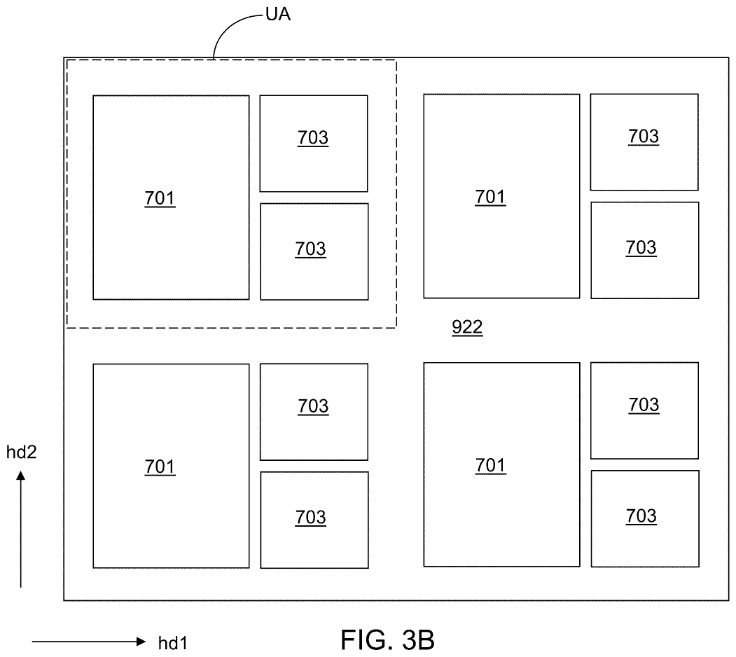

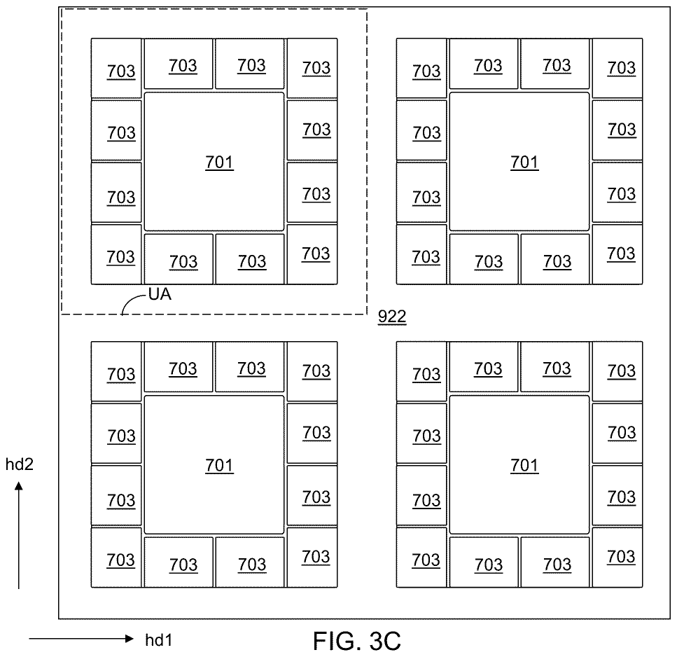

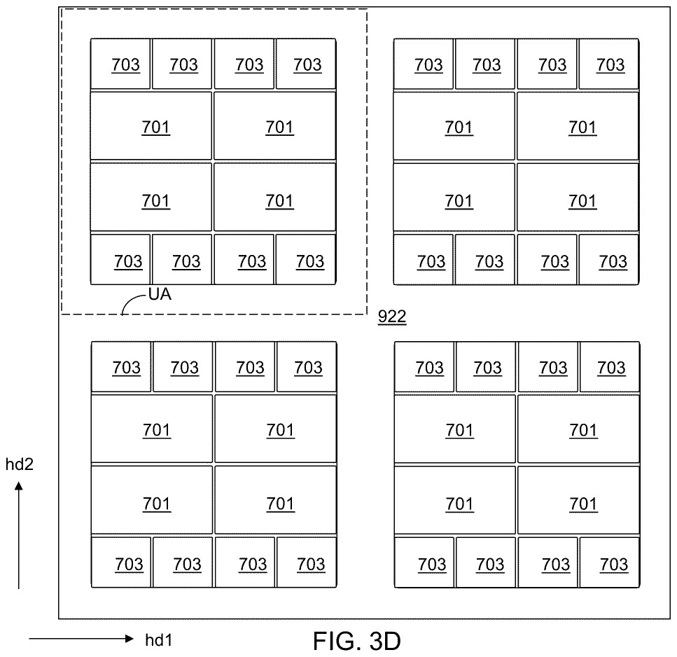

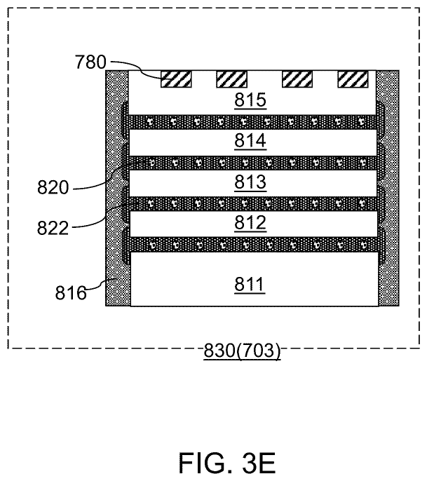

Referring to FIGS. 3A and 3B, a set of at least one semiconductor die (701, 703) may be bonded to each redistribution structure 920. In one embodiment, the redistribution structures 920 may be arranged as a two-dimensional periodic array, and multiple sets of at least one semiconductor die (701, 703) may be bonded to the redistribution structures 920 as a two-dimensional periodic rectangular array of sets of the at least one semiconductor die (701, 703). Each set of at least one semiconductor die (701, 703) includes at least one semiconductor die. Each set of at least one semiconductor die (701, 703) may include any set of at least one semiconductor die known in the art. In one embodiment, each set of at least one semiconductor die (701, 703) may comprise a plurality of semiconductor dies (701, 703). For example, each set of at least one semiconductor die (701, 703) may include at least one system-on-chip (SoC) die 701 and/or at least one memory die 703. Each SoC die 701 may comprise an application processor die, a central processing unit die, or a graphic processing unit die. In one embodiment, the at least one memory die 703 may comprise a high bandwidth memory (HBM) die that includes a vertical stack of static random access memory dies. In one embodiment, the at least one semiconductor die (701, 703) may include at least one system-on-chip (SoC) die and a high bandwidth memory (HBM) die including a vertical stack of static random access memory (SRAM) dies that are interconnected to one another through microbumps and are laterally surrounded by an epoxy molding material enclosure frame.

Each semiconductor die (701, 703) may comprise a respective array of on-die bump structures 780. Each of the semiconductor dies (701, 703) may be positioned in a face-down position such that on-die bump structures 780 face the first solder material portions 940. Each set of at least one semiconductor die (701, 703) may be placed within a respective unit area UA. Placement of the semiconductor dies (701, 703) may be performed using a pick and place apparatus such that each of the on-die bump structures 780 may be placed on a top surface of a respective one of the first solder material portions 940.

Generally, a redistribution structure 920 including on-interposer bump structures 938 thereupon may be provided, and at least one semiconductor die (701, 703) including a respective set of on-die bump structures 780 may be provided. The at least one semiconductor die (701, 703) may be bonded to the redistribution structure 920 using first solder material portions 940 that are bonded to a respective on-interposer bump structure 938 and to a respective one of the on-die bump structures 780.

Each set of at least one semiconductor die (701, 703) may be attached to a respective redistribution structure 920 through a respective set of first solder material portions 940. Each of the at least one cushioning film within a unit area UA may be located outside an area including the at least one semiconductor die (701, 703) in the unit area UA in a plan view. The plan view is a view along a vertical direction, which is the direction that is perpendicular to the planar top surface of the redistribution structure layer.

FIG. 3C is a top-down view of a region of an alternative configuration of the structure of FIG. 3A. FIG. 3D is a top-down view of a region of another alternative configuration of the structure of FIG. 3A. The configurations illustrated in FIGS. 3C and 3D are merely illustrative, and any arrangement of semiconductor dies (701, 703) may be used. Generally, a plurality of semiconductor dies (701, 703) may be attached to each interposer 900. In one embodiment, the plurality of semiconductor dies (701, 703) may comprise at least one SoC die 701 and at least one memory die 703. In one embodiment, each plurality of semiconductor dies (701, 703) attached to a respective interposer 900 may be arranged within a respective rectangular area such that sidewalls of a subset of the respective plurality of semiconductor dies (701, 703) are located at the four sides of the respective rectangular area.

Referring to FIG. 3E, a high bandwidth memory (HBM) die 830 is illustrated, which may be used as a memory die 703. The HBM die 830 may include a vertical stack of static random access memory dies (811, 812, 813, 814, 815) that are interconnected to one another through microbumps 820 and are laterally surrounded by an epoxy molding material enclosure frame 816. The gaps between vertically neighboring pairs of the random access memory dies (811, 812, 813, 814, 815) may be filled with HBM underfill material portions 822 that laterally surrounds a respective set of microbumps 820. The HBM die 830 may comprise an array of on-die bump structures 780 configured to be bonded to a subset of an array of on-interposer bump structures 938 within a unit area UA. The HBM die 830 may, or may not, be configured to provide a high bandwidth as defined under JEDEC standards, i.e., standards defined by The JEDEC Solid State Technology Association.

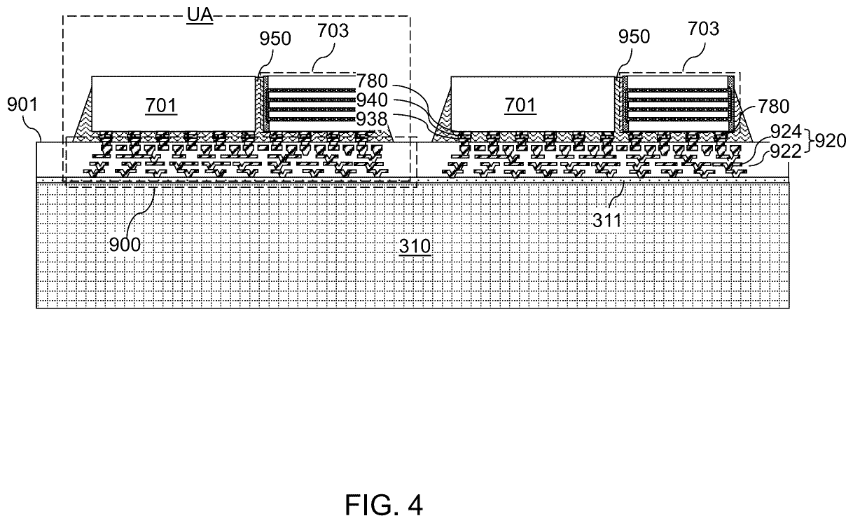

Referring to FIG. 4, a first underfill material may be applied into each gap between the interposers 900 and sets of at least one semiconductor die (701, 703) that are bonded to the interposers 900. The first underfill material may comprise any underfill material known in the art. A first underfill material portion 950 may be formed within each unit area UA between an interposer 900 and an overlying set of at least one semiconductor die (701, 703). The first underfill material portions 950 may be formed by injecting the first underfill material around a respective array of first solder material portions 940 in a respective unit area UA. Any known underfill material application method may be used, which may be, for example, the capillary underfill method, the molded underfill method, or the printed underfill method.

Within each unit area UA, a first underfill material portion 950 may laterally surround, and contact, each of the first solder material portions 940 within the unit area UA. The first underfill material portion 950 may be formed around, and contact, the first solder material portions 940, the on-interposer bump structure 938, and the on-die bump structures 780 in the unit area UA. The first underfill material portion 950 is formed between semiconductor dies (701, 703) and an interposer 900, and thus, is also referred to as a die-interposer underfill material portion, or a DI underfill material portion.

Each interposer 900 in a unit area UA comprises on-interposer bump structure 938. At least one semiconductor die (701, 703) comprising a respective set of on-die bump structures 780 is attached to the on-interposer bump structure 938 through a respective set of first solder material portions 940 within each unit area UA. Within each unit area UA, a first underfill material portion 950 laterally surrounds the on-interposer bump structure 938 and the on-die bump structures 780 of the at least one semiconductor die (701, 703).

Generally, an underfill material portion 950 may be formed between each facing pair of the at least one interposer 900 and at least one set of the at least one semiconductor die (701, 703). In one embodiment, each interposer 900 comprises on-interposer bump structures 938 located above the horizontal plane including the first horizontal surface 901 of the interposer 900, and the horizontally-extending portion of the underfill material portion 950 is located above the horizontal plane including the first horizontal surface 901 of the interposer 900.

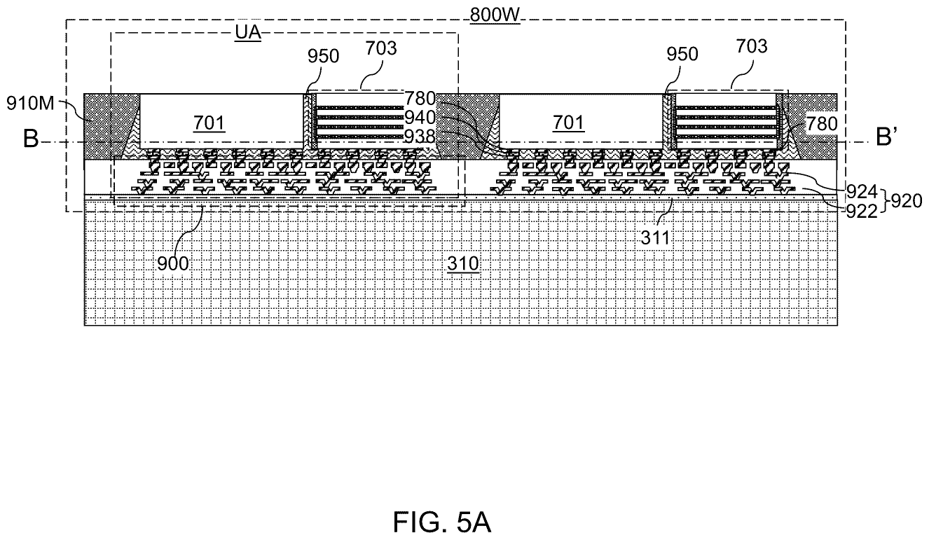

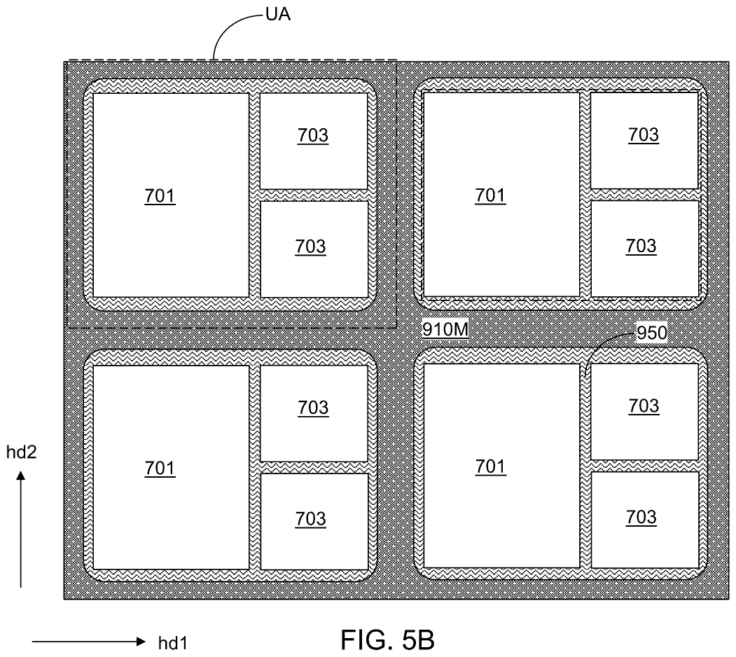

Referring to FIGS. 5A and 5B, an epoxy molding compound (EMC) may be applied to the gaps between contiguous assemblies of a respective set of semiconductor dies (701, 703) and a first underfill material portion 950.

The EMC may include an epoxy-containing compound that may be hardened (i.e., cured) to provide a dielectric material portion having sufficient stiffness and mechanical strength. The EMC may include epoxy resin, hardener, silica (as a filler material), and other additives. The EMC may be provided in a liquid form or in a solid form depending on the viscosity and flowability. Liquid EMC provides better handling, good flowability, less voids, better fill, and less flow marks. Solid EMC provides less cure shrinkage, better stand-off, and less die drift. A high filler content (such as 85% in weight) within an EMC may shorten the time in mold, lower the mold shrinkage, and reduce the mold warpage. Uniform filler size distribution in the EMC may reduce flow marks, and may enhance flowability. The curing temperature of the EMC may be lower than the release (debonding) temperature of the first adhesive layer 311 in embodiments in which the adhesive layer includes a thermally debonding material. For example, the curing temperature of the EMC may be in a range from 125° C. to 150° C.

The EMC may be cured at a curing temperature to form an EMC matrix 910M that laterally surrounds and embeds each assembly of a set of semiconductor dies (701, 703) and a first underfill material portion 950. The EMC matrix 910M includes a plurality of epoxy molding compound (EMC) die frames that may be laterally adjoined to one another. Each EMC die frame is a portion of the EMC matrix 910M that is located within a respective unit area UA. Thus, each EMC die frame laterally surrounds and embeds a respective set of semiconductor dies (701, 703) and a respective first underfill material portion 950. Young's modulus of pure epoxy is about 3.35 GPa, and Young's modulus of the EMC may be higher than Young's modulus of pure epoxy by adding additives. Young's modulus of EMC may be greater than 3.5 GPa.

Portions of the EMC matrix 910M that overlies the horizontal plane including the top surfaces of the semiconductor dies (701, 703) may be removed by a planarization process. For example, the portions of the EMC matrix 910M that overlies the horizontal plane may be removed using a chemical mechanical planarization (CMP). The combination of the remaining portion of the EMC matrix 910M, the semiconductor dies (701, 703), the first underfill material portions 950, and the two-dimensional array of interposers 900 comprises a reconstituted wafer 800W. Each portion of the EMC matrix 910M located within a unit area UA constitutes an EMC die frame.

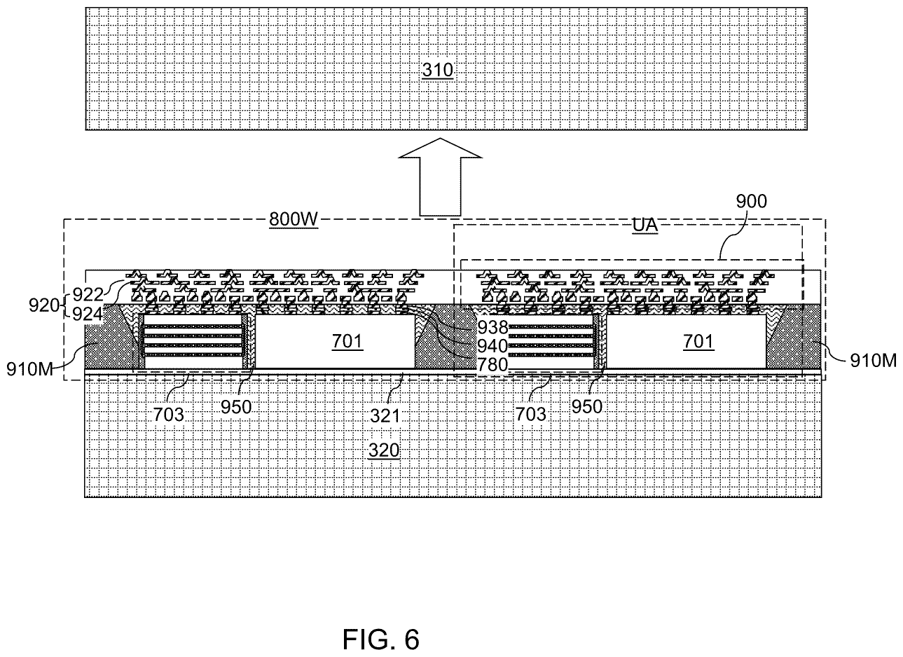

Referring to FIG. 6, a second adhesive layer 321 may be applied to the physically exposed planar surface of the reconstituted wafer 800W, i.e., the physically exposed surfaces of the EMC matrix 910M, the semiconductor dies (701, 703), and the first underfill material portions 950. In one embodiment, the second adhesive layer 321 may comprise a same material as, or may comprise a different material from, the material of the first adhesive layer 311. In embodiments in which the first adhesive layer 311 comprises a thermally decomposing adhesive material, the second adhesive layer 321 may comprise another thermally decomposing adhesive material that decomposes at a higher temperature, or may comprise a light-to-heat conversion material.

A second carrier substrate 320 may be attached to the second adhesive layer 321. The second carrier substrate 320 may be attached to the opposite side of the reconstituted wafer 800W relative to the first carrier substrate 310. Generally, the second carrier substrate 320 may comprise any material that may be used for the first carrier substrate 310. The thickness of the second carrier substrate 320 may be in a range from 500 microns to 2,000 microns, although lesser and greater thicknesses may also be used.

The first adhesive layer 311 may be decomposed by ultraviolet radiation or by a thermal anneal at a debonding temperature. In embodiments in which the first carrier substrate 310 includes an optically transparent material and the first adhesive layer 311 includes an LTHC layer, the first adhesive layer 311 may be decomposed by irradiating ultraviolet light through the transparent carrier substrate. The LTHC layer may absorb the ultraviolet radiation and generate heat, which decomposes the material of the LTHC layer and cause the transparent first carrier substrate 310 to be detached from the reconstituted wafer 800W. In embodiments in which the first adhesive layer 311 includes a thermally decomposing adhesive material, a thermal anneal process at a debonding temperature may be performed to detach the first carrier substrate 310 from the reconstituted wafer 800W.

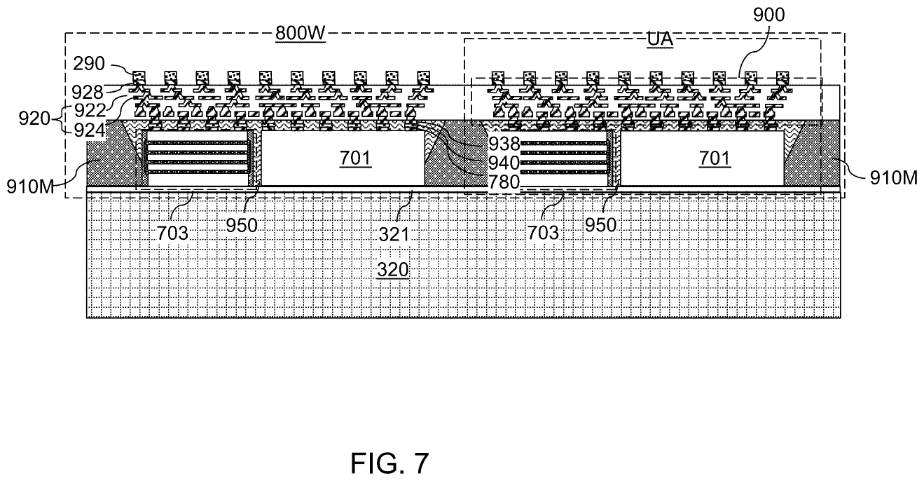

Referring to FIG. 7, bump structures 928 (which may be referred to as backside bump structures) and second solder material portions 290 may be formed by depositing and patterning a stack of at least one metallic material that may function as metallic bumps and a solder material layer. The metallic fill material for the bump structures 928 may include copper. Other suitable materials are within the contemplated scope of disclosure. The thickness of the bump structures 928 may be in a range from 5 microns to 100 microns, although lesser or greater thicknesses may also be used. The bump structures 928 and the second solder material portions 290 may have horizontal cross-sectional shapes of rectangles, rounded rectangles, or circles. Other suitable shapes are within the contemplated scope of disclosure. In embodiments in which the bump structures 928 are formed as C4 (controlled collapse chip connection) pads, the thickness of the bump structures 928 may be in a range from 5 microns to 50 microns, although lesser or greater thicknesses may also be used. In some embodiments, the bump structures 928 may be, or include, under bump metallurgy (UBM) structures. The configurations of the bump structures 928 are not limited to be fan-out structures. Alternatively, the bump structures 928 may be configured for microbump bonding (i.e., C2 bonding), and may have a thickness in a range from 30 microns to 100 microns, although lesser or greater thicknesses may also be used. In such an embodiment, the bump structures 928 may be formed as an array of microbumps (such as copper pillars) having a lateral dimension in a range from 10 microns to 25 microns, and having a pitch in a range from 20 microns to 50 microns.

The bump structures 928 and the second solder material portions 290 may be formed on the opposite side of the EMC matrix 910M and the two-dimensional array of sets of semiconductor dies (701, 703) relative to the interposer layer. The interposer layer includes a three-dimensional array of interposers 900. Each interposer 900 may be located within a respective unit area UA. Each interposer 900 may include redistribution dielectric layers 922, redistribution wiring interconnects 924 embedded in the redistribution dielectric layers 922, and bump structures 928. The bump structures 928 may be located on an opposite side of the on-interposer bump structure 938 relative to the redistribution dielectric layers 922, and may be electrically connected to a respective one of the on-interposer bump structure 938.

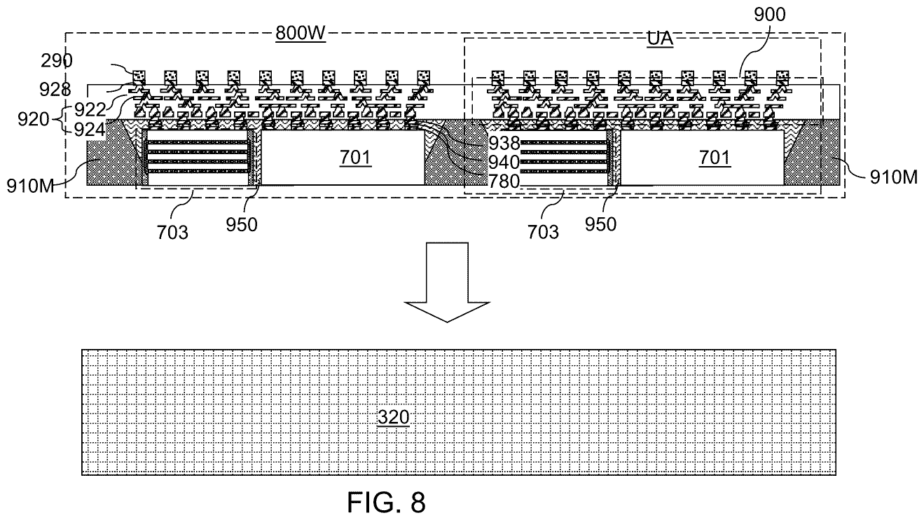

Referring to FIG. 8, the second adhesive layer 321 may be decomposed by ultraviolet radiation or by a thermal anneal at a debonding temperature. In embodiments in which the second carrier substrate 320 includes an optically transparent material and the second adhesive layer 321 includes an LTHC layer, the second adhesive layer 321 may be decomposed by irradiating ultraviolet light through the transparent carrier substrate. In embodiments in which the second adhesive layer 321 includes a thermally decomposing adhesive material, a thermal anneal process at a debonding temperature may be performed to detach the second carrier substrate 320 from the reconstituted wafer 800W.

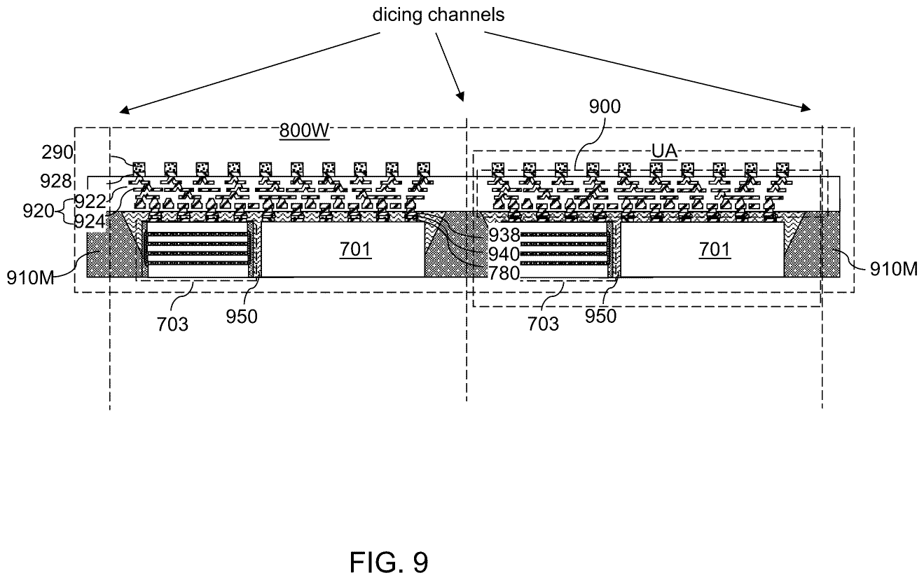

Referring to FIG. 9, the reconstituted wafer 800W including the bump structures 928 may be subsequently diced along dicing channels by performing a dicing process. The dicing channels correspond to the boundaries between neighboring pairs of die areas DA. Each diced unit from the reconstituted wafer 800W may include a semiconductor package 800. In other words, each diced portion of the assembly of the two-dimensional array of sets of semiconductor dies (701, 703), the two-dimensional array of first underfill material portions 950, the EMC matrix 910M, and the two-dimensional array of interposers 900 constitutes a semiconductor package 800. Each diced portion of the EMC matrix 910M constitutes a molding compound die frame 910. Each diced portion of the interposer layer (which includes the two-dimensional array of interposers 900) constitutes an interposer 900.

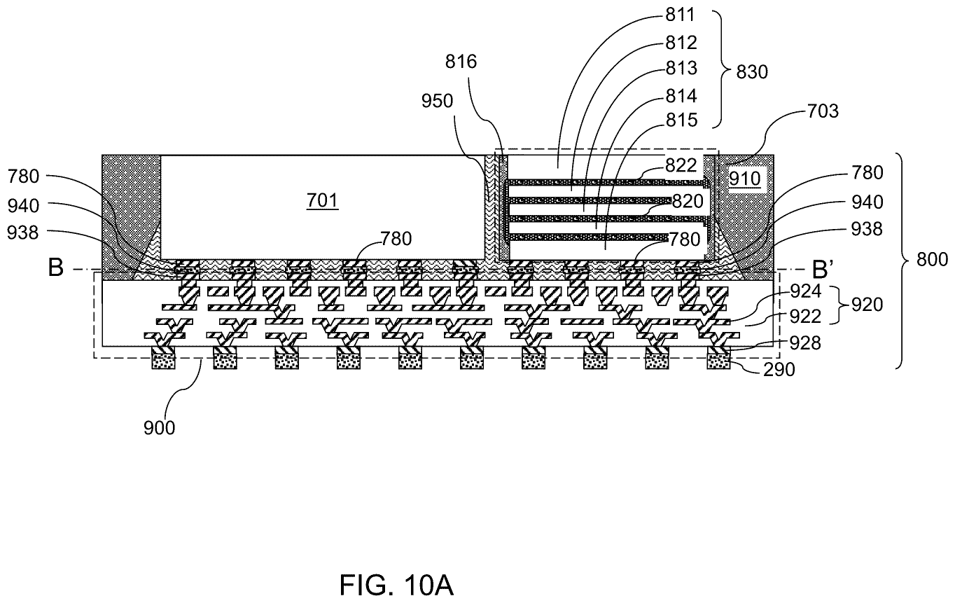

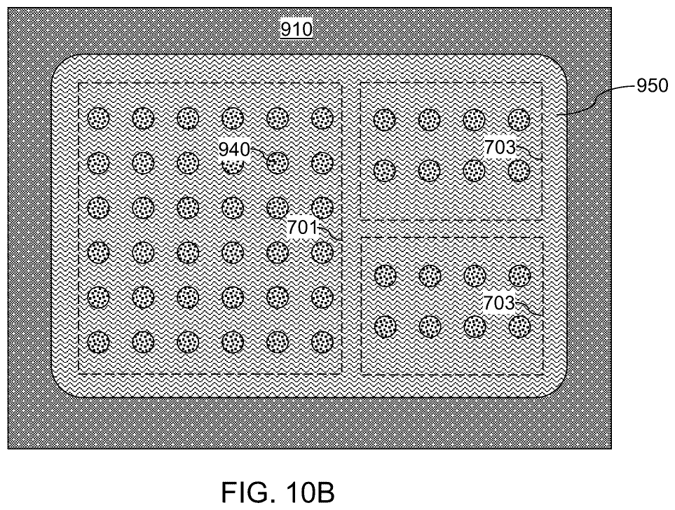

Referring to FIGS. 10A and 10B, a semiconductor package 800 obtained by dicing the structure at the processing steps of FIG. 9 is illustrated. The semiconductor package 800 comprises an interposer 900 including on-interposer bump structure 938, at least one semiconductor die (701, 703) comprising a respective set of on-die bump structures 780 that is attached to the on-interposer bump structure 938 through a respective set of first solder material portions 940, a first underfill material portion 950 laterally surrounding the on-interposer bump structure 938 and the on-die bump structures 780 of the at least one semiconductor die (701, 703).

The semiconductor package 800 may comprise a molding compound die frame 910 laterally surrounding the at least one semiconductor die (701, 703) and comprising a molding compound material. In one embodiment, the molding compound die frame 910 may include sidewalls that are vertically coincident with sidewalls of the interposer 900, i.e., located within same vertical planes as the sidewalls of the interposer 900. Generally, the molding compound die frame 910 may be formed around the at least one semiconductor die (701, 703) after formation of the first underfill material portion 950 within each semiconductor package 800. The molding compound material contacts a peripheral portion of a planar surface of the interposer 900.

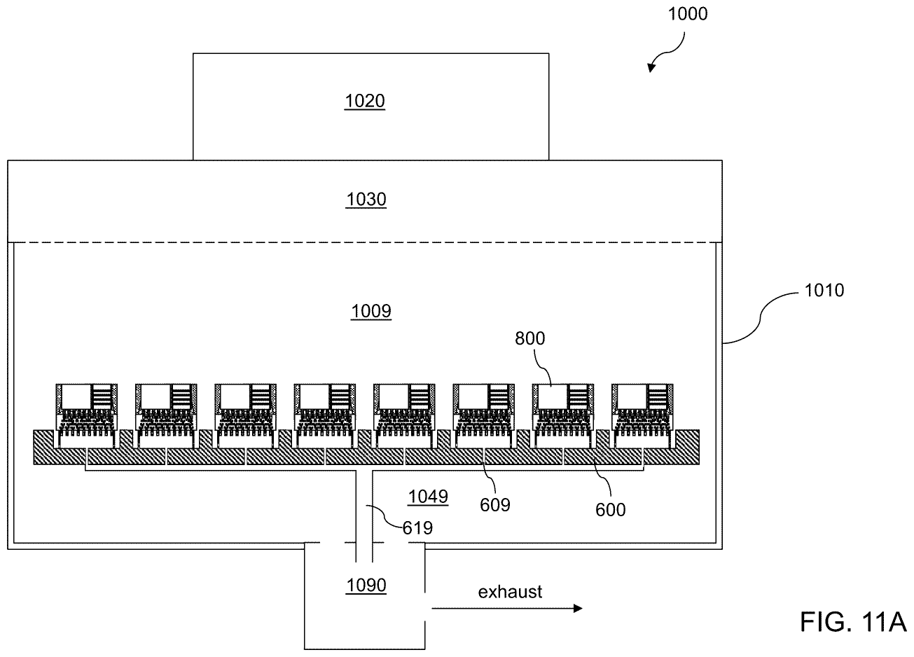

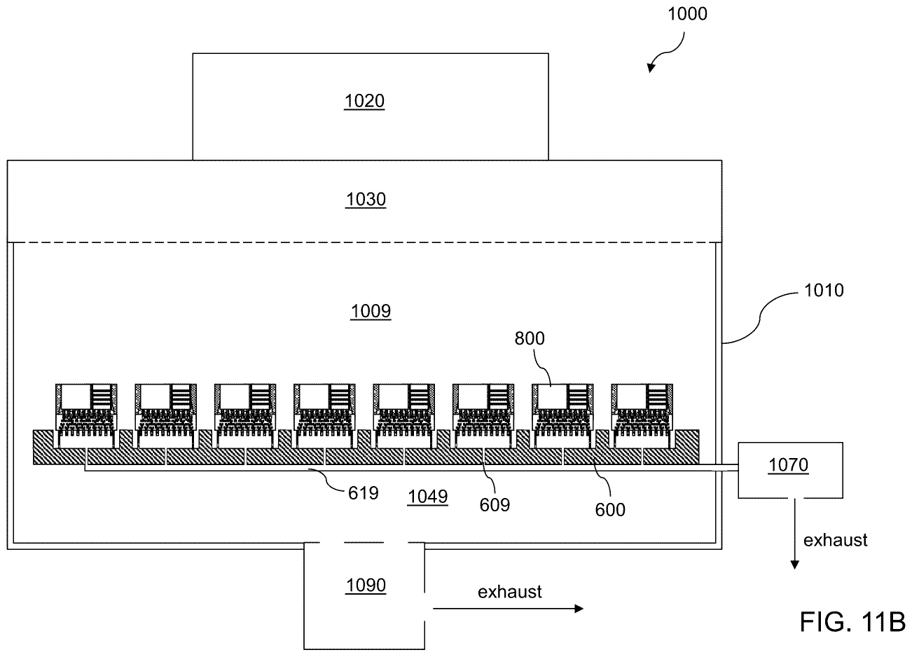

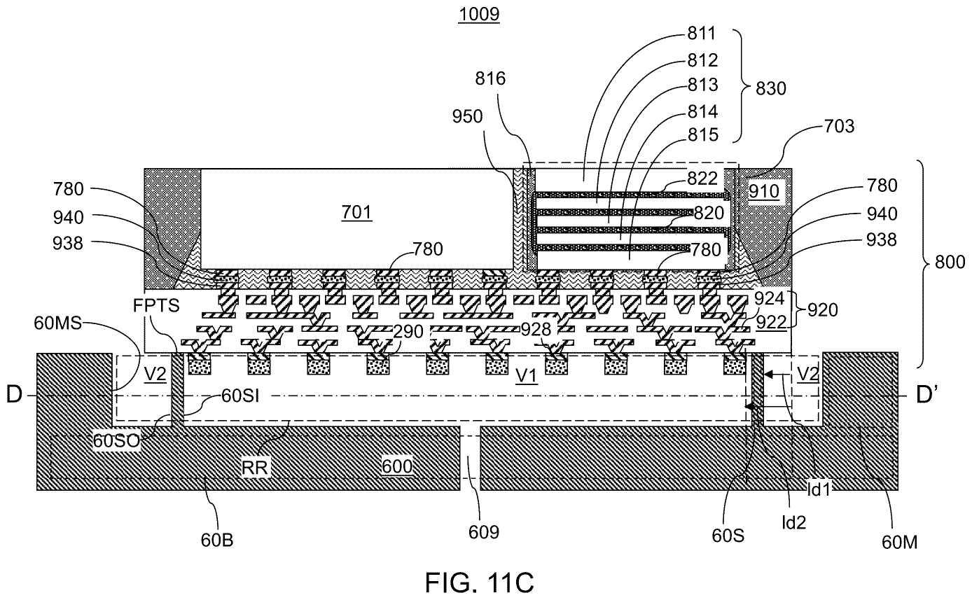

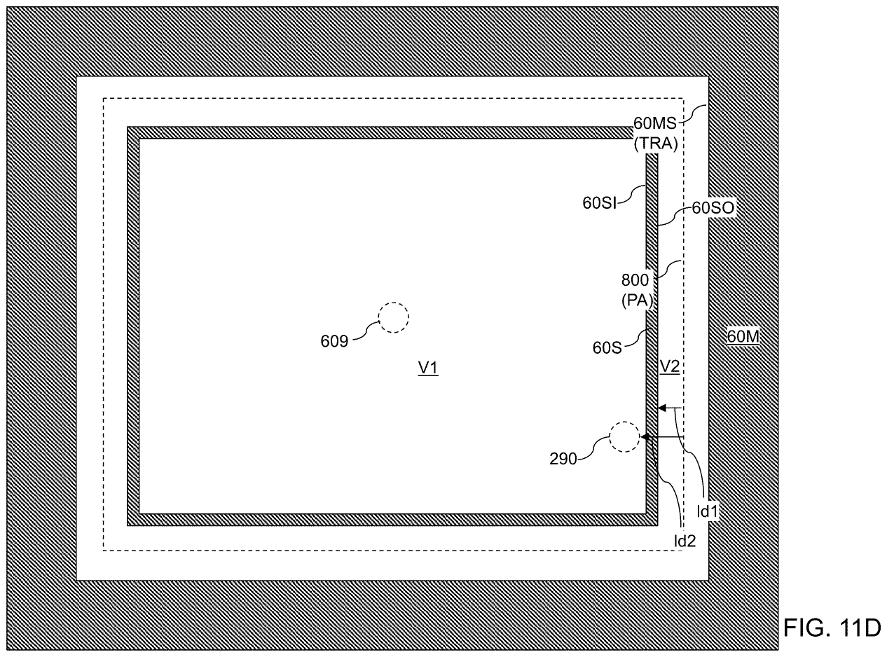

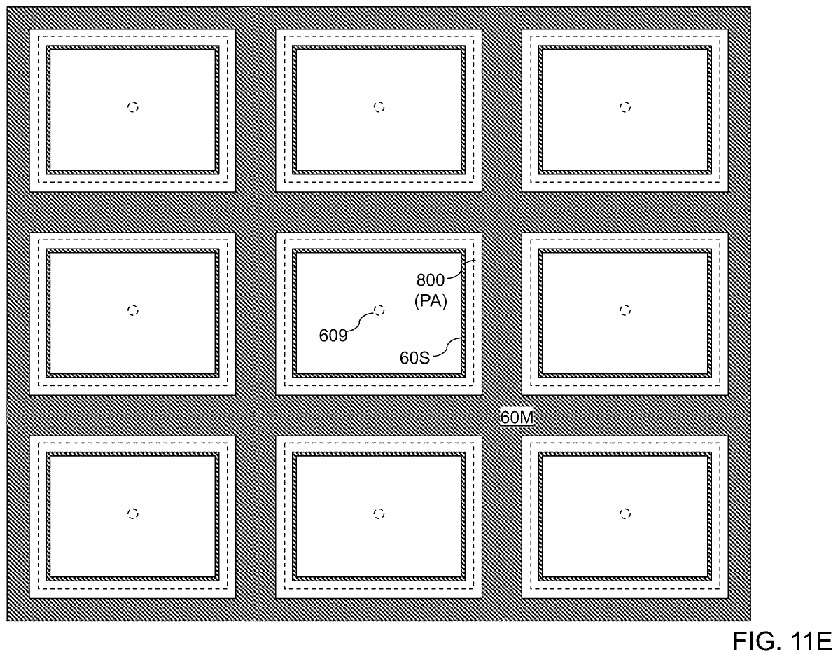

FIG. 11A is a vertical cross-sectional view of an exemplary deposition apparatus 1000 in a first configuration according to an embodiment of the present disclosure. FIG. 11B is a vertical cross-sectional view of an exemplary deposition apparatus 1000 in a second configuration according to an embodiment of the present disclosure. FIG. 11C is a vertical cross-sectional view of a region around a semiconductor package 800 and a region of a package tray 600 after disposing the semiconductor package 800 on the package tray 600 in the first exemplary deposition apparatus 1000 or in the second exemplary deposition apparatus 1000 according to an embodiment of the present disclosure. FIG. 11D is a horizontal cross-sectional view of the portion of the package tray 600 along the horizontal plane D-D′ in FIG. 11C. FIG. 11E is a plan view of a larger portion of the package tray 600 in FIGS. 11C and 11D.

Referring collectively to FIGS. 11A-11E, a deposition apparatus 1000 according to embodiments of the present disclosure is provided. The deposition apparatus 1000 may have a first configuration illustrated in FIG. 11A or in a second configuration illustrated in FIG. 11B. Generally, the deposition apparatus of the present disclosure comprises a chamber enclosure 1010 having an opening for loading and unloading at least one semiconductor die 800. The opening may be provided on a sidewall of the chamber enclosure 1010, and may be configured to transport a package tray 600 with at least one semiconductor package 800 thereupon. Alternatively, the opening may be provided by lifting an upper portion of the chamber enclosure 1010 or by lowering a lower portion of the chamber enclosure 1010. In this embodiment, the upper portion or the lower portion of the chamber enclosure 1010 may be moved with, or without, tilt relative to a fixed portion of the chamber enclosure 1010. A vacuum seal may be provided at a location at which components of the chamber enclosure 1010 are adjoined upon closing of the opening.

The at least one semiconductor package 800 may be loaded into the chamber enclosure 1010 using a package tray 600. The package tray 600 may be configured to hold at least one semiconductor package 800 thereupon. The at least one semiconductor package 800 may be loaded onto the package tray 600 using a pick-and-placement tool while the package tray 600 stays within the chamber enclosure 1010, or while the package tray 600 is temporarily transferred out of the chamber enclosure 1010 for the purpose of loading the at least one semiconductor package 800. The at least one semiconductor package 800 may be a single semiconductor package 800, or may be a plurality of semiconductor packages 800 such as a two-dimensional array of semiconductor packages 800. Typically, at least 16 semiconductor packages 800, such as at least 100 semiconductor packages 800, may be loaded onto the package tray 600. Generally, any type of semiconductor package 800 on which an electromagnetic interference (EMI) shielding film is to be formed may be loaded onto the package tray 600. While the present disclosure is described using an embodiment in which multiple semiconductor packages 800 of the type described with reference to FIGS. 10A and 10B may be loaded onto a package tray 600, it is understood that any type of semiconductor package configured for deposition of an EMI film thereupon may be used in lieu of the illustrated semiconductor packages 800.

According to an aspect of the present disclosure, the package tray 600 may be configured for disposition of at least one semiconductor package 800 thereupon. The package tray 600 comprises a tray base portion 60B, a tray mesa portion 60M which protrudes upward from the tray base portion 60B and laterally enclosing at least one recessed region RR, and at least one frame-shaped support portion 60S. In one embodiment, the tray mesa portion 60M may be configured as a lattice structure in which a first one-dimensional periodic array of first rail portions intersect a second one-dimensional periodic array of second rail portions. The first one-dimensional periodic array of first rail portions laterally extends along a first horizontal direction. The first rail portions have a first uniform width and a first uniform spacing along a second horizontal direction which is perpendicular to the first horizontal direction. The second one-dimensional periodic array of second rail portions laterally extends along the second horizontal direction. The second rail portions have a second uniform width and a second uniform spacing along the first horizontal direction.

Generally, at least one semiconductor package 800 may be disposed on the package tray 600 outside the chamber enclosure 1010 or inside the chamber enclosure 1010. Thus, the at least one semiconductor package 800 may be disposed on the package tray 600 prior to, or after, the package tray 600 is disposed in the chamber enclosure 1010. In embodiments in which the at least one semiconductor package 800 is disposed on the package tray 600 outside the chamber enclosure 1010, the combination of the at least one semiconductor package 800 and the package tray 600 may be transferred into the volume of the chamber enclosure 1010 using a robot. Any opening in the chamber enclosure 1010 may be sealed such that an enclosed volume within the chamber enclosure is isolated from the ambient outside the chamber enclosure 1010.

According to an aspect of the present disclosure, each semiconductor package 800 may be disposed on a respective frame-shaped support portion 60S. The tray base portion 60B laterally extends underneath each of the at least one semiconductor package 800. The tray mesa portion 60M protrudes upward from the tray base portion 60B and comprises at least one contiguous set of mesa-portion sidewalls 60MS, each defining a recessed region RR. The tray mesa portion 60M may comprise multiple contiguous sets of mesa-portion sidewalls 60MS. The total number of the contiguous sets of mesa-portion sidewalls 60MS may be the same as the total number of the recessed regions RR. The total number of the recessed regions RR may be in a range from 1 to 1,000, although a greater number may also be used. In one embodiment, the tray mesa portion 60M may be configured as a two-dimensional array of intersecting rail portions, and may laterally enclose a two-dimensional array of recessed regions RR.

Each semiconductor package 800 defines a package area PA, which is the area of the respective semiconductor package 800 in a plan view, such as a top-down view. Specifically, each package area PA may be defined a set of all sidewalls of a respective semiconductor package 800 in a plan view, and the area enclosed by the set of all sidewalls is the package area PA. Each frame-shaped support portion 60S comprises a continuous set of support-portion outer sidewalls 60SO that is laterally offset inward from the package area PA of an overlying semiconductor package 800. Each of the at least one frame-shaped support portion 60S is located within a respective recessed region RR selected from the at least one recessed region RR, and protrudes upward from the tray base portion 60B.

The deposition apparatus 1000 comprises a reactant gas supply manifold 1030, such as a showerhead, configured to supply a reactant gas to a gas inlet side of the chamber enclosure 1010. A gas flow control system 1020 may be provided upstream of the reactant gas supply manifold 1030. The deposition apparatus 1000 comprises a vacuum pump 1090 connected to an opposite side of the reactant gas supply manifold 1030. The package tray 600 may be positioned within the chamber enclosure 1010 in a manner that divides a first portion of a volume within the chamber enclosure 1010 that is proximal to the reactant gas supply manifold 1030 from a second portion of the volume within the chamber enclosure that is proximal to the vacuum pump 1090. The first portion of the volume within the chamber enclosure 1010 constitutes a reaction region 1009, to which top surfaces, sidewalls, and frame-shaped peripheral bottom surface segments of the semiconductor packages 800 are physically exposed. The second portion of the volume within the chamber enclosure 1010 constitutes an exhaust region 1049, which functions as a conduit for gases that are pumped from the reaction region 1009 into the vacuum pump 1090.

In one embodiment, each of the at least one frame-shaped support portion 60S is configured to divide the respective recessed region RR into a first volume V1 and a second volume V2 upon placement of a semiconductor package 800 thereupon. The first volume V1 is laterally enclosed by a respective frame-shaped support portion 60S and is excluded from the reaction region 1009, and the second volume V2 is located entirely outside the respective frame-shaped support portion 60S and is included in the reaction region 1009, i.e., is a fraction of the reaction region 1009.

In one embodiment, the deposition apparatus 1000 may further comprise a vacuum manifold 619 including at least one opening 609 in the tray base portion 60B. In one embodiment, an opening 609 may be provided through the tray base portion 60B and connecting each first volume V1 of the at least one recessed region RR to the vacuum pump 1090 (as in the embodiment of the first configuration illustrated in FIG. 11A) or to another vacuum pump 1070 (as in the embodiment of the second configuration illustrated in FIG. 11B).

In one embodiment, the semiconductor package 800 comprises an array of bump structures 928, and an array of solder material portions 290 may be attached to the array of bump structures 928 prior to positioning the semiconductor package 800 in the package tray 600, for example, as described with reference to FIGS. 10A and 10B. In one embodiment, each frame-shaped support portion 60S comprises a continuous set of support-portion inner sidewalls 60SI that is laterally offset inward from the continuous set of support-portion outer sidewalls 60SO by a first lateral distance ld1 in a plan view, such as a horizontal cross-sectional view of FIG. 11D in which the package area PA is shown.

In one embodiment, the array of solder material portions 290 may be located entirely within an area defined by the continuous set of support-portion inner sidewalls 60SI in the plan view. For example, outermost surface segments of the solder material portions 290 may be laterally offset from a set of vertical planes including all sidewalls of a respective overlying semiconductor package 800 (i.e., the set of vertical planes defining a package area PA) by a second lateral distance ld2. The second lateral offset distance may be greater than the lateral distance between each support-portion inner sidewalls 60SI and a most proximal vertical plane including a sidewall of an overlying semiconductor package 800.

In one embodiment, the array of solder material portions 290 is positioned such that the array of solder material portions 290 is not in direct contact with any surface of the package tray 600. In one embodiment, the frame-shaped support portion 60S laterally encloses an entirety of the array of solder material portions 290 of an overlying semiconductor package 800 upon disposing the overlying semiconductor package 800 on the package tray 600.

In one embodiment, the frame-shaped support portion 60S comprises a frame-shaped planar top surface FPTS, and the entirety of the frame-shaped planar top surface FPTS is contacted by a frame-shaped bottom surface segment of the semiconductor package 800 upon disposing the overlying semiconductor package 800 on the package tray 600. In one embodiment, each of the at least one frame-shaped support portion 60S comprises a respective frame-shaped planar top surface FPTS that is located within a horizontal plane including a top surface of the tray mesa portion 60M. In other words, each frame-shaped support portion 60S comprises a frame-shaped planar top surface FPTS that is located with the same horizontal plane as the top surface of each tray mesa portion 60M.

In one embodiment, the array of solder material portions 290 may be vertically spaced from the tray base portion 60B upon disposing the semiconductor package 800 on the package tray 600. In one embodiment, the entirety of the array of solder material portions 290 is located below a horizontal plane including an entirety of a contact area between the semiconductor package 800 and the package tray 600.

In one embodiment, the contiguous set of mesa-portion sidewalls 60MS of each tray mesa portion 60M defines a tray recess area TRA in a plan view. Thus, the periphery of the tray recess area TRA coincides within the contiguous set of mesa-portion sidewalls 60MS in the plan view. In one embodiment, the entirety of the periphery of the tray recess area TRA is laterally offset outward from the periphery of the package area PA of an overlying semiconductor package 800 in the plan view

In one embodiment, each semiconductor package 800 is in contact with a frame-shaped support portion 60S upon disposing the semiconductor package 800 on the package tray 600. In one embodiment, each semiconductor package 800 is not in contact with any tray base portion 60B or with any tray mesa portion 60M upon disposing the semiconductor package 800 on the package tray 600. In one embodiment, each semiconductor package 800 is in directly contact with the package tray 600 only at a frame-shaped planar top surface FPTS of a respective frame-shaped support portion 60S of the package tray 600.

In one embodiment, the contact between the semiconductor package 800 and a frame-shaped planar top surface FPTS of the frame-shaped support portion 60S of the package tray 600 provides a seal that prevents diffusion of gases between a first volume V1 of the recessed region RR that is laterally enclosed within the frame-shaped support portion 60S and a second volume V2 of the recessed region RR that is located outside the frame-shaped support portion 60S.

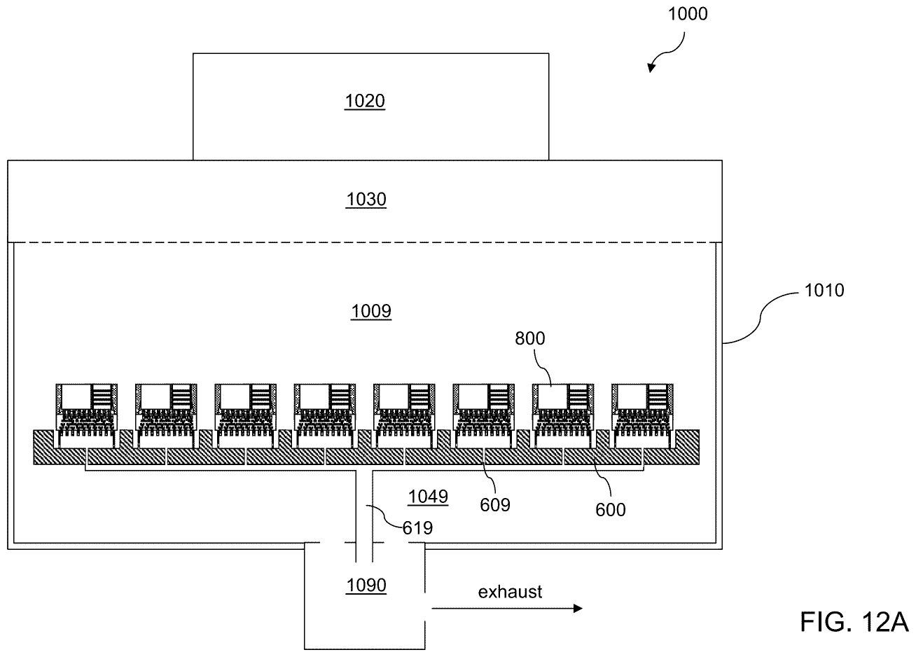

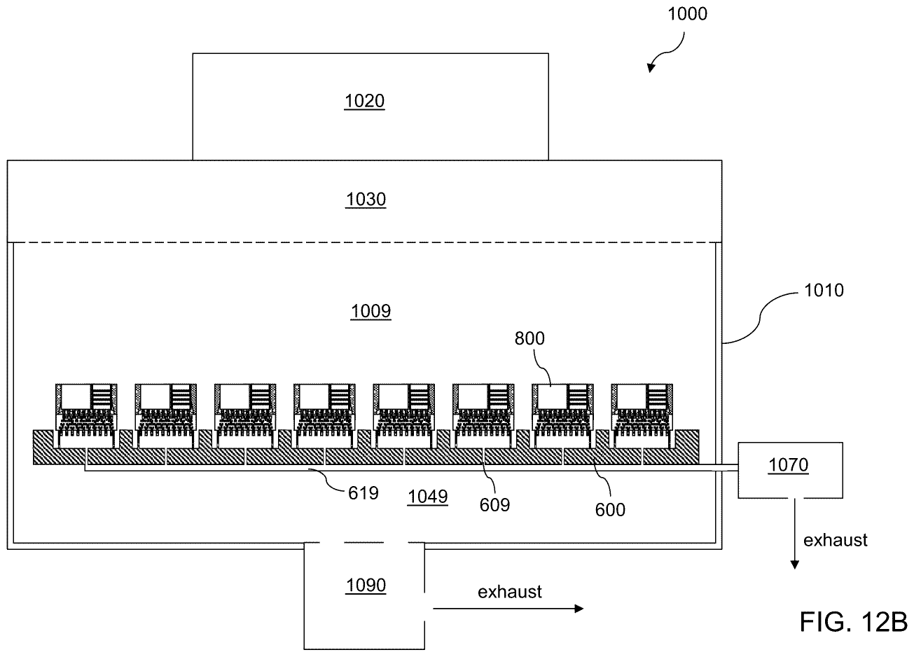

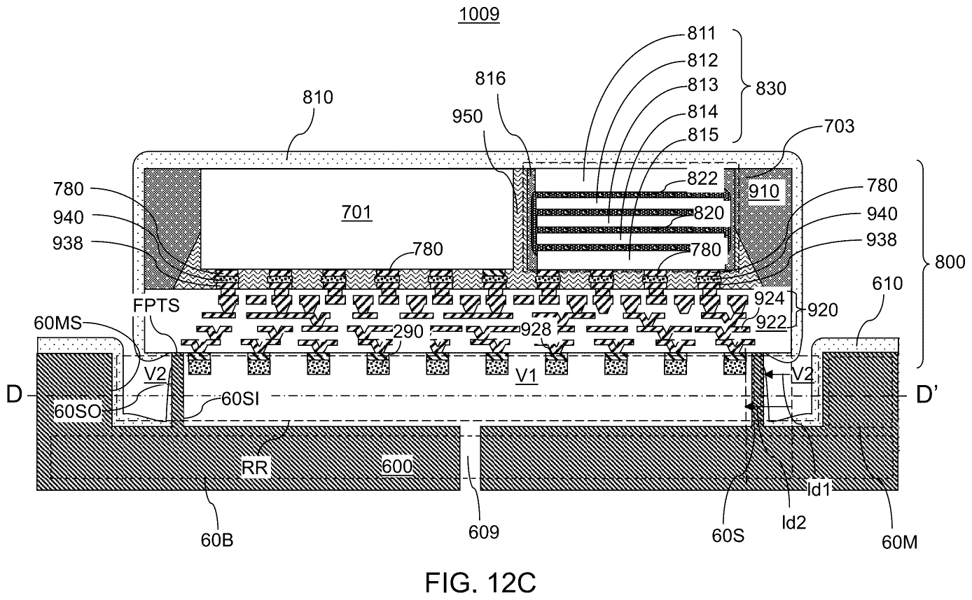

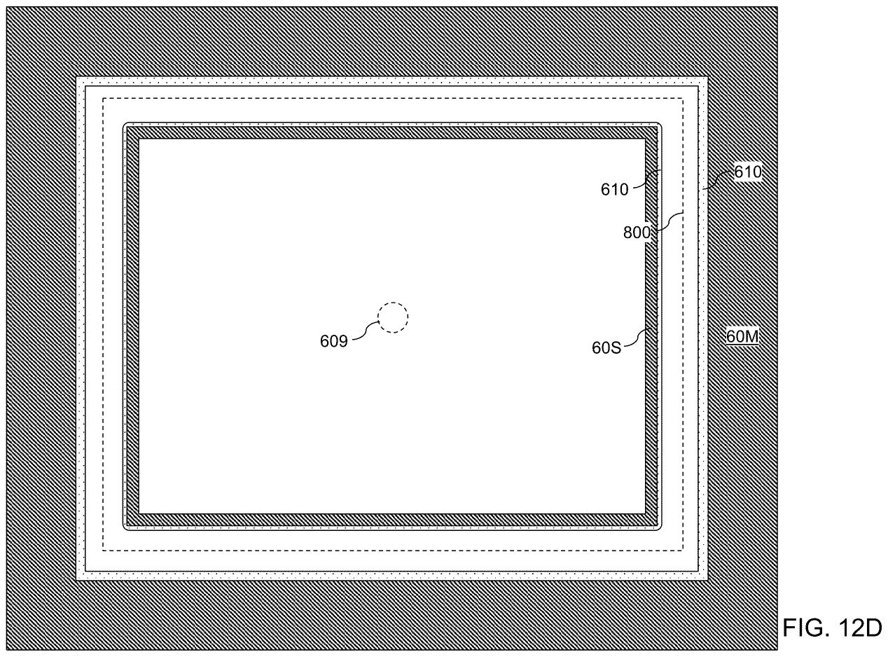

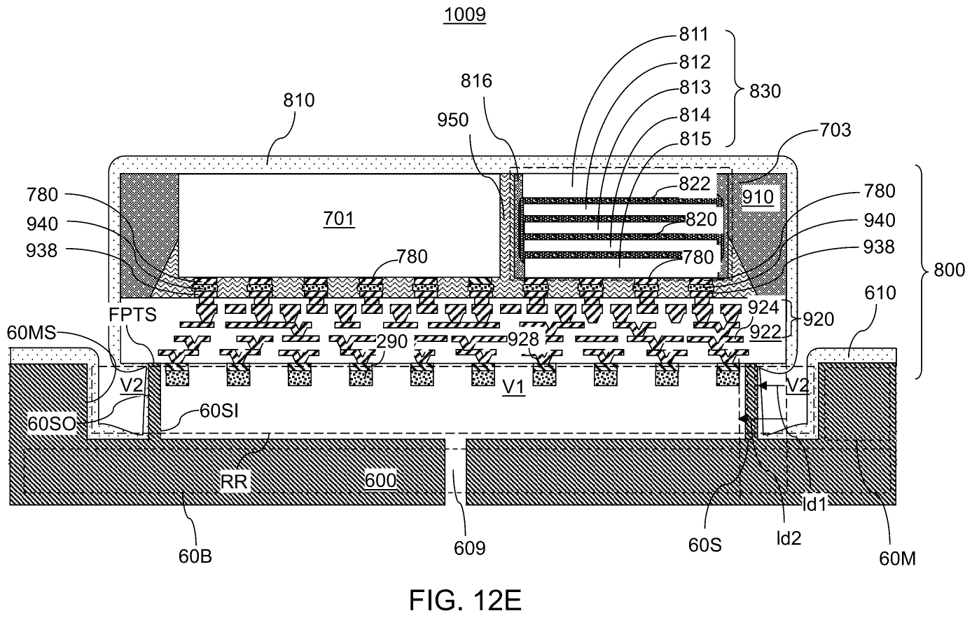

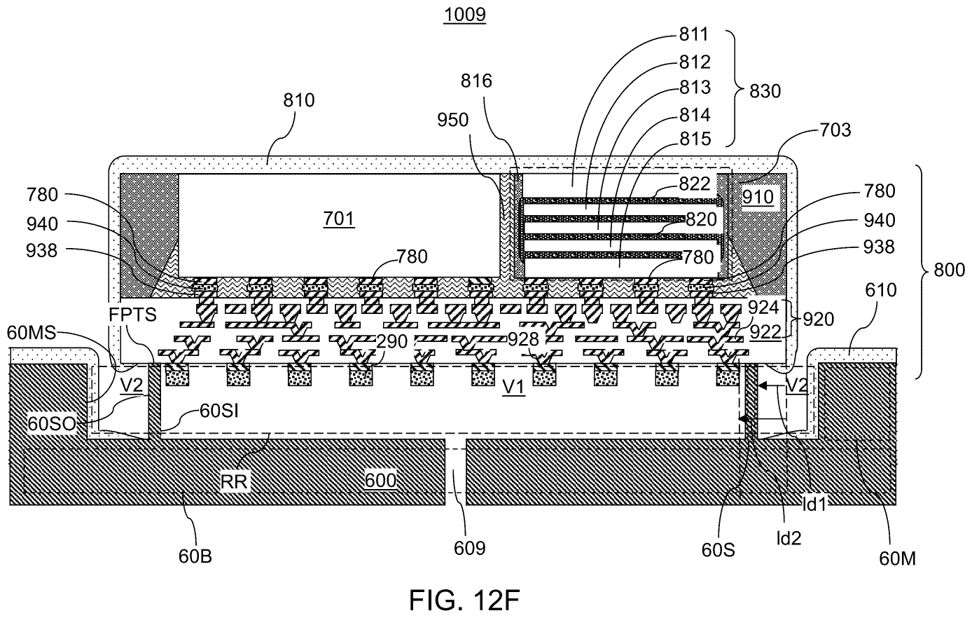

FIG. 12A is a vertical cross-sectional view of the exemplary deposition apparatus 1000 in the first configuration at an end of an electromagnetic interference (EMI) shielding film deposition process according to an embodiment of the present disclosure. FIG. 12B is a vertical cross-sectional view of the exemplary deposition apparatus 1000 in the second configuration at the end of an EMI shielding film deposition process according to an embodiment of the present disclosure. FIG. 12C is a vertical cross-sectional view of a region around a semiconductor package 800 and a region of a package tray 600 in a first configuration at the end of an EMI shielding film deposition process according to an embodiment of the present disclosure. FIG. 12D is a horizontal cross-sectional view of the portion of the package tray 600 along the horizontal plane D-D′ in FIG. 12C. FIG. 12E is a vertical cross-sectional view of a region around a semiconductor package 800 and a region of a package tray 600 in a second configuration at the end of an EMI shielding film deposition process according to an embodiment of the present disclosure. FIG. 12F is a vertical cross-sectional view of a region around a semiconductor package 800 and a region of a package tray 600 in a third configuration at the end of an EMI shielding film deposition process according to an embodiment of the present disclosure.

Referring collectively to FIGS. 12A-12F, an electromagnetic interference (EMI) shielding film 810 may be anisotropically deposited on the set of all sidewalls of each semiconductor package 800 and on the top surface of each semiconductor package 800. Further, the EMI shielding film 810 may be deposited on at least a portion of the frame-shaped physically exposed surface segments of the bottom surface of each semiconductor package 800 that is exposed to the reaction region 1009. Generally, an anisotropic chemical vapor deposition process, such as a plasma-enhanced chemical vapor deposition process, may be used to deposit an EMI shielding film 810 on each semiconductor package 800. A reaction gas and an optional carrier gas may be flowed from the gas flow control system 1020 through the reactant gas supply manifold 1030 (which may comprise a showerhead) into the reaction region 1009 located within the volume of the chamber enclosure 1010. The reactant gas comprises a precursor gas for deposition of the EMI shielding film 810.

Generally, each EMI shielding film 810 is anisotropically deposited on a respective one of the semiconductor packages 800 by flowing a reactant gas into the chamber enclosure 1010. A top surface and sidewalls of each semiconductor package 800 are exposed to a first ambient that comprises the reactant gas and fills the reaction region 1009. The second volume V2 of each recessed region RR may be a portion of the first ambient. A center region of the bottom surface of each semiconductor package 800 is exposed to a vacuum environment that is free of the reactant gas. The first volume V1 of each recessed region RR may be a portion of the vacuum environment. Thus, a peripheral frame-shaped surface segment of the bottom surface of each semiconductor package 800 is exposed to the first ambient during deposition of the EMI shielding film 810. An electromagnetic interference (EMI) shielding material layer 610 may be collaterally deposited on the top surfaces and sidewalls of each tray mesa portion 60M, and on surface segments of the frame-shaped support portions 60S and the tray base portion 60B that are located around the second volumes V2 of the recessed regions RR.

According to an aspect of the present disclosure, the anisotropic nature of the EMI shielding film deposition process causes the vertical thickness of the horizontally-extending portion of each EMI shielding film 810 overlying a top surface of a respective semiconductor package 800 to be greater than the lateral thickness of the vertically-extending portions of each EMI shielding film 810 located on sidewalls of the respective semiconductor package 800. Further, the vertical thickness of each frame-shaped portion of each EMI shielding film 810 contacting a frame-shaped peripheral surface segment of the bottom surface of a respective semiconductor package 800 may decrease from outside to inside.

The degree of change in the vertical thickness of each frame-shaped portion of each EMI shielding film 810 depends on the degree of lateral diffusion of the reactant gas of the anisotropic deposition process. In other words, the degree of change in the vertical thickness of each frame-shaped portion of each EMI shielding film 810 depends on how severe the depletion of the reactant gas is in a region that is shielded by an overlying structure (such as an overlying semiconductor package 800) as a function of a lateral distance from a portion of the reaction region 1009 that is not shielded by any overlying structure. FIG. 12C illustrates a medium reactant-depletion embodiment in which the vertical thickness of the frame-shaped portion of each EMI shielding film 810 reaches zero when the EMI shielding film 810 reaches an outer sidewall of a respective frame-shaped support portion 60S. FIG. 12E illustrates a low reactant-depletion embodiment in which the vertical thickness of the frame-shaped portion of each EMI shielding film 810 does not reach zero at a top periphery of an outer sidewall of a respective frame-shaped support portion 60S. In this embodiment, the EMI shielding film 810 may have a small, but finite, thickness at a junction with the top periphery of an outer sidewall of a respective frame-shaped support portion 60S. FIG. 12F illustrates a high reactant-depletion embodiment in which the vertical thickness of the frame-shaped portion of each EMI shielding film 810 reaches zero before each EMI shielding film 810 reaches an outer sidewall of a respective frame-shaped support portion 60S. In this embodiment, another frame-shaped bottom surface segment of a semiconductor package 800 is not covered by the EMI shielding film 810.

According to an aspect of the present disclosure, the EMI shielding film 810 of the present disclosure may comprise a metallic material such as copper (Cu), silver (Ag), or nickel (Ni), which offer high electrical conductivity for effective EMI attenuation and high mechanical strength for structural robustness. Materials like silver (Ag) and copper (Cu) may be used to provide superior conductivity, which enhances the shielding effectiveness, particularly in high-frequency applications. Copper provides excellent electrical and thermal properties. Silver provides lower oxidation potential and long-term performance stability. Nickel may be used for magnetic shielding applications due to its high permeability, which aids in shielding against low-frequency magnetic fields. In some embodiments, a layer stack including multiple metallic materials may be used for the EMI shielding film 810.

Other materials, including conductive polymers or carbon-based nanomaterials such as graphene or carbon nanotubes, may be used in lieu of, or in addition to, a metallic material to enhance flexibility of the EMI shielding film 810 while reducing the weight of the EMI shielding film 810. For non-metallic applications, conductive polymers like polyaniline (PANI) and poly(3,4-ethylenedioxythiophene) (PEDOT) may be used as EMI shielding materials due to lightweight and mechanical flexibility, which are desirable characteristic for portable or flexible electronic applications. Carbon-based materials, such as graphene and carbon nanotubes may be used for their excellent electrical properties, mechanical strength, and the ability to be integrated into composite structures. Use of a composite layer stack of multiple materials for the EMI shielding film 810 may enhance the effectiveness of the EMI shielding film 810 to block, absorb, and/or reflect unwanted electromagnetic waves.

The EMI shielding film 810 may be deposited using a chemical vapor deposition (CVD) process. The chemical vapor deposition process provides precise thickness control of the EMI shielding film 810. The thickness uniformity of the EMI shielding film across multiple semiconductor packages 800 may be maintained by tuning process parameters such as temperature distribution across the semiconductor packages 800, gas flow rates, and pressure. The chemical vapor deposition process may be made anisotropic by providing a depletive deposition condition, in which the reactant gas is depleted in areas that are not directly exposed to the reactant gas supply manifold 1030. Thus, less molecules of the reactant gas impinges on the physically exposed frame-shaped surface segments of the bottom surfaces of the semiconductor packages 800 relative to the sidewalls of the semiconductor packages 800. As discussed above, a thinner layer of the EMI shielding film 810 having a non-uniform thickness may be deposited on physically exposed frame-shaped surface segments of the bottom surfaces of the semiconductor packages 800.

In an anisotropic deposition process used to deposit the EMI shielding film 810 on each semiconductor package 800, the high directionality of the gas phase reactants in CVD causes that the exposed sidewalls and top surfaces of the semiconductor packages 800 to receive full and uniform deposition, whereas areas shielded by geometric features or fixturing—such as the frame-shaped bottom surface segments of the semiconductor packages 800—receive less deposition. This controlled variability in film thickness across different regions allows for no deposition or minimal deposition of the EMI shielding material at, or around, peripheries of contact areas between the semiconductor packages 800 and the package tray 600. Thus, formation of burrs or unintended bridges between the semiconductor packages 800 and the package tray 600 may be eliminated, or may be minimized.

Further, the frame-shaped contact areas at the frame-shaped planar top surface FPTS of the frame-shaped support portion 60S provide isolation of ambient conditions between the first volume V1 of each recessed region RR and the second volume V2 of each recessed region RR. Thus, contamination or undesirable coating of sensitive components, such as the solder material portions 290, by the reactant gas during the chemical vapor deposition process may be avoided by the geometry of the package tray 600 of the present disclosure.

The thickness of the horizontally-extending portion of each EMI shielding film 810 on a top surface of a respective one of the semiconductor packages 800 may be in a range from 2 micron to 10 microns, although lesser or greater thicknesses may also be used. The thickness of the horizontally-extending portion of each EMI shielding film 810 on a sidewalls of a respective one of the semiconductor packages 800 may be in a range from 1 micron to 5 microns, although lesser or greater thicknesses may also be used. The optimal film thickness for the EMI shielding films 810 may be selected based on the specific electromagnetic interference environment to which the semiconductor package 800 is likely to be subsequently exposed. Generally, thicker films providing more effective shielding are suitable for high-power applications, and thinner films are suitable for miniaturized devices requiring light weight.

The overall shielding effectiveness (SE) of the EMI shielding film 810 may be measured in decibels (dB), with typical values ranging from 40 dB to 90 dB depending on the material composition and the thickness of the EMI shielding film 810. For instance, an EMI shielding film 810 comprising silver may achieve higher shielding effectiveness due to their superior conductivity, while an EMI shielding film 810 comprising nickel may be better suited for applications involving both electric and magnetic interference due to their dual conductive and magnetic properties.

Generally, the anisotropic CVD deposition process allows for highly controlled EMI shielding film deposition, optimizing material usage while ensuring that the top surface and all sidewalls of each semiconductor package 800 receive full protection from electromagnetic interference.

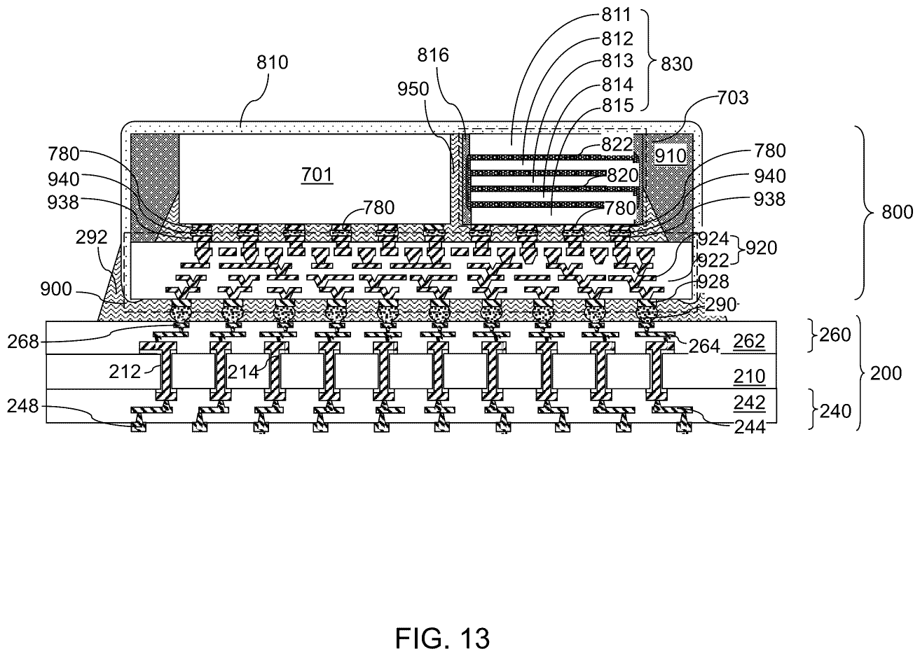

Referring to FIG. 13, a packaging substrate 200 is provided. The packaging substrate 200 may be a cored packaging substrate including a core substrate 210, or a coreless packaging substrate that does not include a package core. Alternatively, the packaging substrate 200 may include a system-on-integrated packaging substrate (SoIS) including redistribution layers and/or dielectric interlayers, at least one embedded interposer (such as a silicon interposer). Such a system-integrated packaging substrate may include layer-to-layer interconnections using solder material portions, microbumps, underfill material portions (such as molded underfill material portions), and/or an adhesion film. While the present disclosure is described using an substrate package, it is understood that the scope of the present disclosure is not limited by any particular type of substrate package and may include an SoIS. The core substrate 210 may include a glass epoxy plate including an array of through-plate holes. An array of through-core via structures 214 including a metallic material may be provided in the through-plate holes. Each through-core via structure 214 may, or may not, include a cylindrical hollow therein. Optionally, dielectric liners 212 may be used to electrically isolate the through-core via structures 214 from the core substrate 210.

The packaging substrate 200 may include board-side surface laminar circuit (SLC) 240 and a chip-side surface laminar circuit (SLC) 260. The board-side SLC may include board-side insulating layers 242 having board-side wiring interconnects 244 formed therein. The chip-side SLC 260 may include chip-side insulating layers 262 embedding chip-side wiring interconnects 264. The board-side insulating layers 242 and the chip-side insulating layers 262 may include a photosensitive epoxy material that may be lithographically patterned and subsequently cured. The board-side wiring interconnects 244 and the chip-side wiring interconnects 264 may include copper that may be deposited by electroplating within patterns in the board-side insulating layers 242 or the chip-side insulating layers 262.

In one embodiment, the packaging substrate 200 includes a chip-side surface laminar circuit 260 comprising chip-side wiring interconnects 264 connected to an array of chip-side bonding pads 268 that may be bonded to the array of second solder material portions 290, and a board-side surface laminar circuit 240 including board-side wiring interconnects 244 connected to an array of board-side bonding pads 248. The array of board-side bonding pads 248 is configured to allow bonding through solder balls. The array of chip-side bonding pads 268 may be configured to allow bonding through C4 solder balls. Generally, any type of packaging substrate 200 may be used. While the present disclosure is described using an embodiment in which the packaging substrate 200 includes a chip-side surface laminar circuit 260 and a board-side surface laminar circuit 240, embodiments are expressly contemplated herein in which one of the chip-side surface laminar circuit 260 and the board-side surface laminar circuit 240 is omitted, or is replaced with an array of bonding structures such as microbumps. In an illustrative example, the chip-side surface laminar circuit 260 may be replaced with an array of microbumps or any other array of bonding structures.

A semiconductor package 800 comprising an EMI shielding film 810 may be disposed over the packaging substrate 200 with an array of the second solder material portions 290 therebetween. In embodiments in which the second solder material portions 290 are formed on the bump structures 928 of the semiconductor package 800, the second solder material portions 290 may be disposed on the chip-side bonding pads 268 of the packaging substrate 200. A reflow process may be performed to reflow the second solder material portions 290, thereby inducing bonding between the semiconductor package 800 and the packaging substrate 200. Each second solder material portion 290 may be bonded to a respective one of the bump structures 928 and to a respective one of the chip-side bonding pads 268. In one embodiment, the second solder material portions 290 may include C4 solder balls, and the semiconductor package 800 may be attached to the packaging substrate 200 through an array of C4 solder balls. Generally, the semiconductor package 800 may be bonded to the packaging substrate 200 such that the interposer 900 is bonded to the packaging substrate 200 by an array of solder material portions (such as the second solder material portions 290).

A second underfill material portion 292 may be formed around the second solder material portions 290 by applying and shaping a second underfill material. The second underfill material portion 292 may be formed by injecting the second underfill material around the array of second solder material portions 290 after the second solder material portions 290 are reflowed. Any known underfill material application method may be used, which may be, for example, the capillary underfill method, the molded underfill method, or the printed underfill method.

The second underfill material portion 292 may be formed between the interposer 900 and the packaging substrate 200. The second underfill material portion 292 may contact each of the second solder material portions 290 (which may be C4 solder balls or C2 solder caps), and may contact vertical sidewalls of the semiconductor package 800. The second underfill material portion laterally surrounds, and contacts, the array of second solder material portions 290 and the semiconductor package 800.

In one embodiment, the semiconductor package 800 comprises a molding compound die frame 910 that laterally surrounds the at least one semiconductor die (701, 703) and contacting a peripheral portion of a top surface of the interposer 900. The second underfill material portion 292 may be formed directly on sidewalls of the molding compound die frame 910.

Generally, an assembly (such as a semiconductor package 800) comprising an interposer 900 and semiconductor dies (701, 703) is provided. The assembly may be attached to a packaging substrate 200 using an array of solder material portions (such as second solder material portions 290).

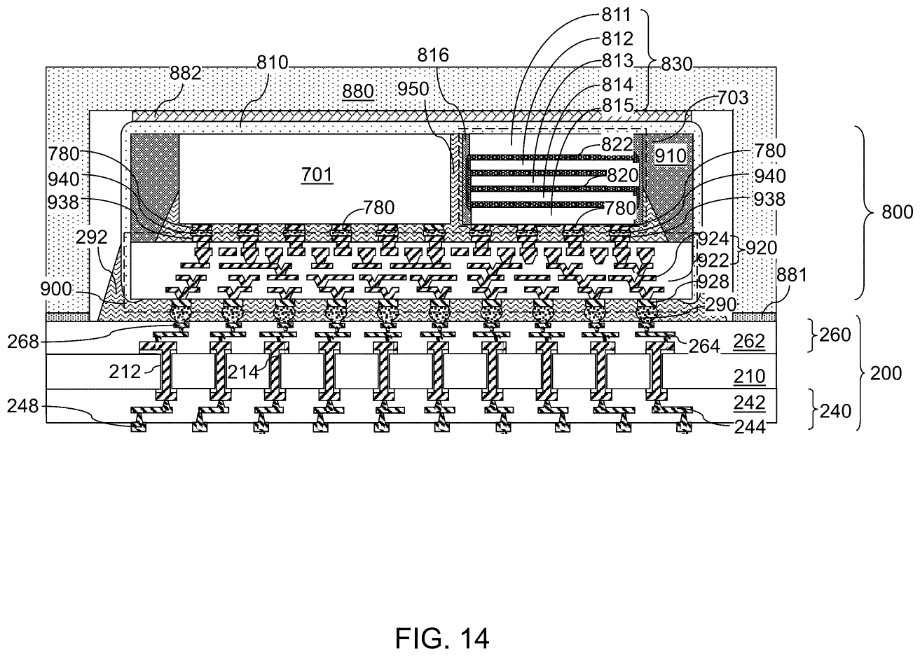

Referring to FIG. 14, a lid structure 880 may be attached to packaging substrate 200 using an adhesive layer 881. The lid structure 880 may comprise a horizontal capping plate and four sidewall plates extending downward from the periphery of the horizontal capping plate. A bottom surface of the horizontal capping plate may be attached to the top surface of the horizontally-extending portion of the EMI shielding film 810 by a thermal interface material (TIM) layer 882. In one embodiment, TIM layer 882 may have thermal conductivity that is greater than about 2 W/m·K, and/or greater than 10 W/m·K, and/or greater than 50 W/m·K.

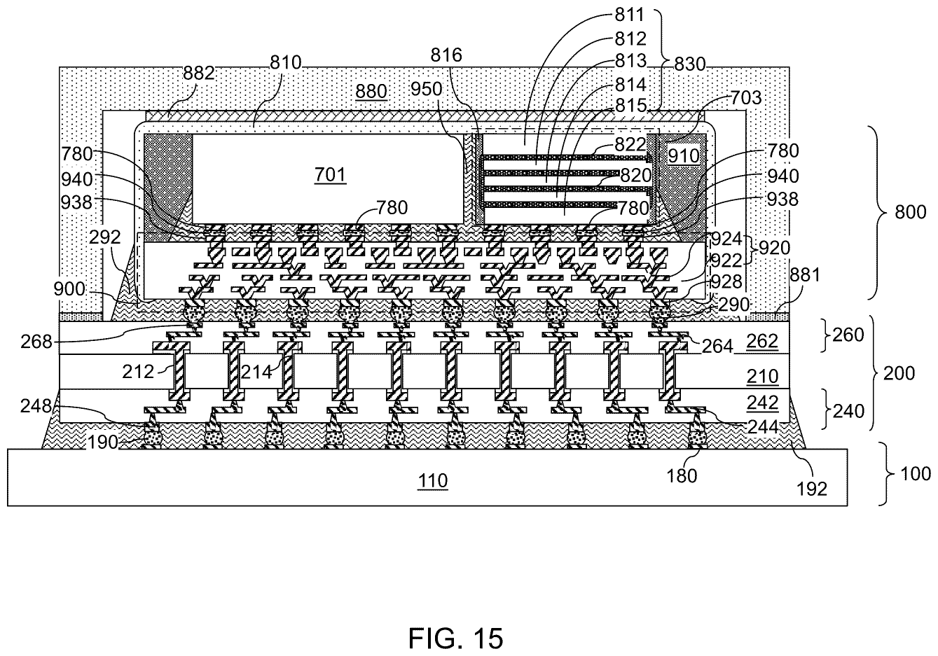

Referring to FIG. 15, a printed circuit board (PCB) 100 including a PCB substrate 110 and PCB bonding pads 180 may be provided. The PCB 100 includes a printed circuitry (not shown) at least on one side of the PCB substrate 110. An array of solder joints 190 may be formed to bond the array of board-side bonding pads 248 to the array of PCB bonding pads 180. The solder joints 190 may be formed by disposing an array of solder balls between the array of board-side bonding pads 248 and the array of PCB bonding pads 180, and by reflowing the array of solder balls. An underfill material portion 192 may be formed around the solder joints 190 by applying and shaping an underfill material. The packaging substrate 200 is attached to the PCB 100 through the array of solder joints 190.

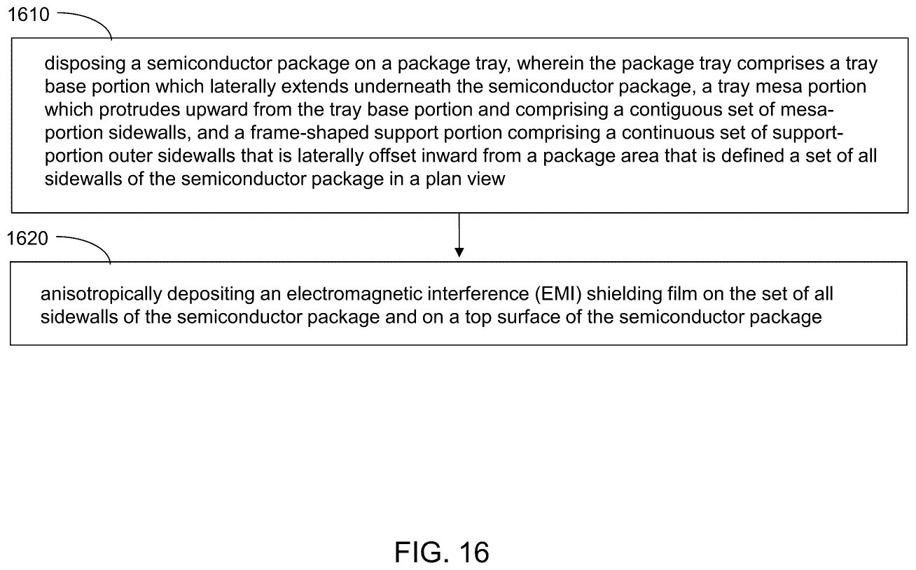

FIG. 16 is a first flowchart illustrating steps for forming an electromagnetic shielding film 810 on a semiconductor package 800 according to an embodiment of the present disclosure.

Referring to step 1610 and FIGS. 1A-11E, a semiconductor package 800 may be disposed on a package tray 600. The package tray 600 comprises a tray base portion 60B which laterally extends underneath the semiconductor package 800, a tray mesa portion 60M which protrudes upward from the tray base portion 60B and comprising a contiguous set of mesa-portion sidewalls 60MS, and a frame-shaped support portion 60S comprising a continuous set of support-portion outer sidewalls 60SO that is laterally offset inward from a package area PA that is defined by a set of all sidewalls of the semiconductor package 800 in a plan view.

Referring to step 1620 and FIGS. 12A-15, an electromagnetic interference (EMI) shielding film 810 may be anisotropically deposited on the set of all sidewalls of the semiconductor package 800 and on a top surface of the semiconductor package 800.

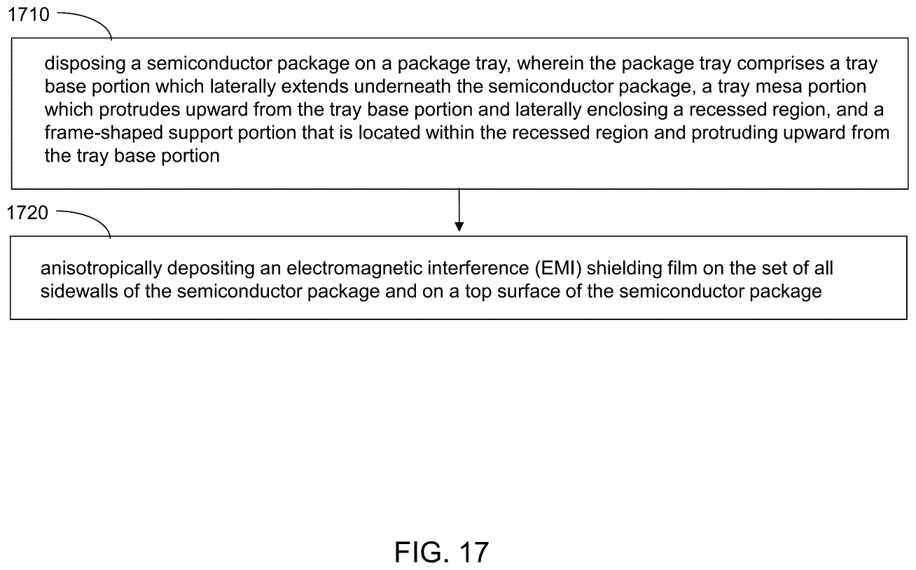

FIG. 17 is a second flowchart illustrating steps for forming an electromagnetic shielding film 810 on a semiconductor package 800 according to an embodiment of the present disclosure.

Referring to step 1710 and FIGS. 1A-11E, a semiconductor package 800 may be disposed on a package tray 600. The package tray 600 comprises a tray base portion 60B which laterally extends underneath the semiconductor package 800, a tray mesa portion 60M which protrudes upward from the tray base portion 60B and laterally enclosing a recessed region RR, and a frame-shaped support portion 60S that is located within the recessed region RR and protrudes upward from the tray base portion 60B.

Referring to step 1720 and FIGS. 12A-15, an electromagnetic interference (EMI) shielding film 810 may be deposited on the set of all sidewalls of the semiconductor package 800 and on a top surface of the semiconductor package 800.

Embodiments of the present disclosure prevents backside contamination of solder material portions 290 during deposition of an EMI shielding film 810, thereby avoiding short circuits and device failure. The package tray 600 of the present disclosure is configured to prevent exposure of the solder material portions 290 to the reactant gas during formation of the EMI shielding film 810. Thus, the EMI shielding film 810 is not formed on the solder material portions 290 or on the central surface segment of the bottom surface of the semiconductor package 800 around the array of solder material portions 290.

Further, embodiments of the present disclosure prevent formation of a continuous EMI film between a semiconductor package 800 and the package tray 600. Thus, formation of burrs around interfaces between the semiconductor package 800 and the package tray 600 may be avoided, and malfunction during picking of the semiconductor package 800 with an EMI shielding film 810 thereupon may be avoided. In other words, errors during handling of the processed semiconductor package 800 after formation of the EMI shielding film 810 thereupon may be avoided due to absence of burr formation around the interfaces between the semiconductor package 800 and the package tray 600. Specifically, each frame-shaped support portion 60S may be laterally recessed inward from sidewalls of an overlying semiconductor package 800 by a first lateral distance ld1 so that formation of a continuous EMI film between the semiconductor package 800 and the package tray 600 is avoided, or the thickness of a continuous EMI film around each interface between the semiconductor package 800 and the package tray 600 is minimized to a thickness that is typically less than 0.1 micron, and preferably less than 50 nm.

Embodiments of the present disclosure may provide complete coating of the entire area of all sidewalls of a semiconductor package 800. This feature prevents reduction of the effectiveness of the EMI shielding by ensuring that the EMI shielding film 810 covers the entire area of all sidewalls of the semiconductor package 800, thereby enhancing the shielding performance and providing improved protection against electromagnetic interference.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a device structure, comprising:
disposing a semiconductor package on a package tray, wherein the package tray comprises a tray base portion which laterally extends underneath the semiconductor package, a tray mesa portion which protrudes upward from the tray base portion and comprising a contiguous set of mesa-portion sidewalls, and a frame-shaped support portion comprising a continuous set of support-portion outer sidewalls that is laterally offset inward from a package area that is defined by a set of all sidewalls of the semiconductor package in a plan view; and
anisotropically depositing an electromagnetic interference (EMI) shielding film on the set of all sidewalls of the semiconductor package and on a top surface of the semiconductor package.

2. The method of claim 1, wherein:
the semiconductor package comprises an array of bump structures; and
the method comprises attaching an array of solder material portions to the array of bump structures prior to positioning the semiconductor package in the package tray.

3. The method of claim 2, wherein:
the frame-shaped support portion comprises a continuous set of support-portion inner sidewalls that is laterally offset inward from the continuous set of support-portion outer sidewalls in the plan view; and
the array of solder material portions is located entirety within an area defined by the continuous set of support-portion inner sidewalls in the plan view.

4. The method of claim 2, wherein the array of solder material portions is not in direct contact with any surface of the package tray.

5. The method of claim 2, wherein the frame-shaped support portion laterally encloses an entirety of the array of solder material portions upon disposing the semiconductor package on the package tray.

6. The method of claim 2, wherein:
the frame-shaped support portion comprises a frame-shaped planar top surface; and
an entirety of the frame-shaped planar top surface is contacted by a frame-shaped bottom surface segment of the semiconductor package upon disposing the semiconductor package on the package tray.

7. The method of claim 2, wherein:
the array of solder material portions is vertically spaced from the tray base portion upon disposing the semiconductor package on the package tray; and
an entirety of the array of solder material portions is located below a horizontal plane including an entirety of a contact area between the semiconductor package and the package tray.

8. The method of claim 1, wherein:
the contiguous set of mesa-portion sidewalls of the tray mesa portion defines a tray recess area in the plan view; and
an entirety of a periphery of the tray recess area is laterally offset outward from a periphery of the package area in the plan view.

9. The method of claim 8, wherein the frame-shaped support portion comprises a frame-shaped planar top surface that is located with a same horizontal plane as a top surface of the tray mesa portion.

10. The method of claim 1, wherein:
the semiconductor package is in contact with the frame-shaped support portion upon disposing the semiconductor package on the package tray; and
the semiconductor package is not in contact with the tray base portion or with the tray mesa portion upon disposing the semiconductor package on the package tray.

11. A method of manufacturing a device structure, comprising:
disposing a semiconductor package on a package tray, wherein the package tray comprises a tray base portion which laterally extends underneath the semiconductor package, a tray mesa portion which protrudes upward from the tray base portion and laterally enclosing a recessed region, and a frame-shaped support portion that is located within the recessed region and protrudes upward from the tray base portion; and
anisotropically depositing an electromagnetic interference (EMI) shielding film on a set of all sidewalls of the semiconductor package and on a top surface of the semiconductor package.

12. The method of claim 11, wherein the semiconductor package is in directly contact with the package tray only at a frame-shaped planar top surface of the frame-shaped support portion of the package tray.

13. The method of claim 11, wherein a contact between the semiconductor package and a frame-shaped planar top surface of the frame-shaped support portion of the package tray provides a seal that prevents diffusion of gases between a first volume of the recessed region that is laterally enclosed within the frame-shaped support portion and a second volume of the recessed region that is located outside the frame-shaped support portion.

14. The method of claim 11, further comprising disposing the package tray in a chamber enclosure, wherein:
the semiconductor package is disposed on the package tray prior to, or after, the package tray is disposed in the chamber enclosure; and
the EMI shielding film is anisotropically deposited by flowing a reactant gas into the chamber enclosure such that a top surface and sidewalls of the semiconductor package are exposed to a first ambient that comprises the reactant gas, and a center region of the a bottom surface of the semiconductor package is exposed to a vacuum environment that is free of the reactant gas.

15. The method of claim 14, wherein a peripheral frame-shaped surface segment of the bottom surface of the semiconductor package is exposed to the first ambient during deposition of the EMI shielding film.

16. A deposition apparatus comprising:
a chamber enclosure;
a package tray configured for disposition of at least one semiconductor package thereupon, wherein the package tray comprises a tray base portion, a tray mesa portion which protrudes upward from the tray base portion and laterally enclosing at least one recessed region, and at least one frame-shaped support portion, wherein each of the at least one frame-shaped support portion is located within a respective recessed region selected from the at least one recessed region and protrudes upward from the tray base portion;
a vacuum pump connected to an exhaust region of the chamber enclosure; and
a reactant gas supply manifold configured to supply a reactant gas to a gas inlet side of the chamber enclosure and to provide a reaction region within the chamber enclosure.

17. The deposition apparatus of claim 16, wherein each of the at least one frame-shaped support portion comprises a respective frame-shaped planar top surface that is located within a horizontal plane including a top surface of the tray mesa portion.

18. The deposition apparatus of claim 16, wherein the reactant gas comprises a precursor gas for deposition of an electromagnetic interference (EMI) shielding film.

19. The deposition apparatus of claim 16, wherein:
each of the at least one frame-shaped support portion is configured to divide the respective recessed region into a first volume and a second volume upon placement of a semiconductor package thereupon;
the first volume is laterally enclosed by a respective frame-shaped support portion and is excluded from the reaction region; and
the second volume is located entirely outside the respective frame-shaped support portion and is a fraction of the reaction region.

20. The deposition apparatus of claim 19, further comprising a vacuum manifold including at least one opening in the tray base portion and connecting each first volume of the at least one recessed region to the vacuum pump or to another vacuum pump.
